(19) United States
(12) Patent Application Publication
(10) Pub. No.: US 2022/0005961 A1
(43) Pub. Date: Jan. 6, 2022

(54) Photoelectric Detector And Method of Making The Same

(71) Applicant: SiFotonics Technologies Co., Ltd., Grand Cayman (KY)

(72) Inventors: Fan Qi, Beijing (CN); Tzung-I Su, Taoyuan City (TW); Bin Shi, Beijing (CN); Pengfei Cai, Beijing (CN); Dong Pan, Andover, MA (US)

(21) Appl. No.: 17/359,564

(22) Filed: Jun. 27, 2021

(30) Foreign Application Priority Data
Jul. 2, 2020 (CN) 2020106328937

(51) Int. Cl. H01L 31/0232; G02B 6/122; G02B 6/12

(52) U.S. Cl. CPC H01L 31/02327; H01L 31/107; G02B 6/12004; G02B 6/1228

(57) ABSTRACT

Various embodiments of a photodetector having a reflector are described. The photodetector includes a waveguide layer disposed on top of a substrate, an avalanche multiplication detection region disposed on top of the waveguide layer, and a reflector disposed adjacent to a rear surface of the waveguide layer. The waveguide layer includes a narrower input section and a wider detection section concatenated with the input section. The waveguide layer may also include a tapering section having a changing width that follows the detection section. The reflector may be a one-dimensional photonic crystal, a two-dimensional photonic crystal, or a bulk material. A careful design of the reflector and the waveguide layer of the photodetector is helpful in achieving a high responsivity and a high operation speed at the same time.

### CROSS-REFERENCE TO RELATED PATENT APPLICATIONS

The present disclosure claims the priority benefit of Chinese Patent Application No. 2020106328937, filed on Jul. 2, 2020. The aforementioned application is incorporated by reference in its entirety.

### TECHNICAL FIELD

The present disclosure relates to the technical field of photoelectric detection devices. More particularly, the present disclosure relates to a waveguide avalanche multiplication photoelectric detector having an integrated reflector, as well as a manufacturing method for making the same.

### BACKGROUND

Photoelectric devices have been widely used for highspeed optical communication and optical Internet. On the one hand, the absorption coefficient of absorption materials that are often used in optical communication, e.g., germanium, would rapidly drop as the signal wavelength exceeds 1550 nanometer (nm) or as the ambient temperature reduces. On the other hand, the design of photoelectric detection devices is often subjected to a tradeoff between a requirement of high detection responsivity and a requirement of high operation bandwidth. For example, in designing a waveguide photoelectric detector, the former requirement would demand an increase in the waveguide length (i.e., the length of the detector cavity), whereas the latter requirement would demand a reduction in the detector cavity length. Even in the design of a waveguide photoelectric detector, the limitation, i.e., the tradeoff, remains, although likely at a lesser degree, but is not eliminated. This is because an increased cavity length would cause an increased capacitance, making the RC time constant of the waveguide photoelectric detector a main factor that limits the operation bandwidth.

### SUMMARY

An object of the present disclosure is to provide a photodetector having a reflector integrated therein. A simplified design of the reflector presented below only contains planar structures, and thus is beneficial in reducing manufacturing cost of the photodetector while enhancing its performance.

In one aspect, a photodetector is provided. The photodetector includes a waveguide layer disposed on top of a substrate, an avalanche multiplication detection region disposed on top of the waveguide layer, and a reflector disposed adjacent to a rear surface of the waveguide layer. The waveguide layer may include a narrower input section and a wider detection section concatenated with the input section. The waveguide layer may further include a rear surface, wherein the rear surface is located at an end of the detection section opposing the input section. The avalanche multiplication detection region may include a multiplication layer disposed on top of the waveguide layer, and an absorption layer disposed on top of the multiplication layer. The avalanche multiplication detection region may also include a top contact layer disposed on top of the absorption layer. The reflector may be a one-dimensional photonic crystal, a two-dimensional photonic crystal, or a bulk material.

In some embodiments, the reflector is substantially aligned with the waveguide layer in a z-direction, i.e., the direction that is perpendicular to the main surface of the substrate.

In some embodiments, the reflector is substantially aligned with a combination of the waveguide layer and the multiplication layer in the z-direction.

In some embodiments, the reflector has a top edge that is higher than a top edge of the multiplication layer in the z-direction, as well as a bottom edge that is lower than a bottom edge of the waveguide layer in the z-direction.

In some embodiments, the reflector may be a one-dimensional photonic crystal that is realized by a plurality of one-dimensional grooves that are periodically arranged in the waveguide layer.

In some embodiments, the reflector may be a two-dimensional photonic crystal that is realized by an array of holes or columns that are periodically arranged in the waveguide layer.

In some embodiments, the reflector may be a two-dimensional photonic crystal that is realized by an array of holes or columns that are periodically arranged in both the waveguide layer and the multiplication layer.

In some embodiments, the reflector has a flat reflective surface. In some embodiments, the reflector has a concave reflective surface.

In some embodiments, the reflector is bulk material having a concave reflective surface located at a rear end of the bulk material. The refractive index of the bulk material is greater than or equal to that of the waveguide layer.

In some embodiments, the reflector is bulk material having a concave reflective surface located at a front end of the bulk material. The refractive index of the bulk material less than that of the waveguide layer.

In another aspect, another photodetector is provided. The photodetector includes a waveguide layer disposed on top of a substrate, an avalanche multiplication detection region disposed on top of the waveguide layer, and a reflector disposed adjacent to a rear surface of the waveguide layer. The waveguide layer may include a narrower input section and a wider detection section concatenated with the input section. The waveguide layer may also include a tapering section that is concatenated with the detection section and opposing the input section. Starting from the end of the detection section at which the tapering section is adjacent to, the tapering section extends from a first location towards a second location with a changing width. In some embodiments, the tapering section may extend from the first location towards the second location with a gradually reducing width. The waveguide layer may further include a rear surface, wherein the rear surface is located at an end of the tapering section opposing the input section, i.e., at the second location. The avalanche multiplication detection region may include a multiplication layer disposed on top of the waveguide layer, and an absorption layer disposed on top of the multiplication layer. The avalanche multiplication detection region may also include a top contact layer disposed on top of the absorption layer. The reflector may be a one-dimensional photonic crystal, a two-dimensional photonic crystal, or a bulk material.

The embodiments of the present disclosure have various beneficial technical effects, including at least: (1) a simplified design of the reflector; (2) a lower fabrication cost of the photodetector; (3) an enhanced photodetector responsivity; and (4) achieving high responsivity and high operation speed (i.e., shorter response time) simultaneously.

### BRIEF DESCRIPTION OF THE DRAWINGS

In order to clearly explain specific embodiments according to the present disclosure or technical solutions according to prior art, a brief description of accompanying drawings required by descriptions on the specific embodiments or the prior art is given below. Obviously, the drawings described as follows illustrate certain embodiments of the present disclosure. For an ordinary one skilled in the art, without any creative work, other drawings may also be derived or otherwise obtained according to these drawings.

FIG. 1A illustrates a top view of a waveguide avalanche multiplication photodetector according to a first embodiment of the present disclosure, wherein the reflector is substantially aligned with the waveguide layer in the z-direction.

FIG. 1B illustrates a side view of the waveguide avalanche multiplication photodetector of FIG. 1A.

FIG. 2A illustrates a top view of a waveguide avalanche multiplication photodetector according to a second embodiment of the present disclosure, wherein the reflector is substantially aligned with a combination of the waveguide layer and the multiplication layer in the z-direction.

FIG. 2B illustrates a side view of the waveguide avalanche multiplication photodetector of FIG. 2A.

FIG. 3A illustrates a top view of a waveguide avalanche multiplication photodetector according to a third embodiment of the present disclosure, wherein the top edge of the reflector is higher than that of the multiplication layer in the z-direction, and wherein the lower edge of the reflector extends into the substrate in the z-direction.

FIG. 3B illustrates a side view of the waveguide avalanche multiplication photodetector of FIG. 3A.

FIG. 4A illustrates a top view of a waveguide avalanche multiplication photodetector according to a fourth embodiment of the present disclosure, wherein a tapering section of waveguide that is becoming narrower in the y-direction is horizontally disposed at the end of the waveguide layer, and wherein the multiplication layer is not in touch with the tapering section of waveguide.

FIG. 4B illustrates a side view of the waveguide avalanche multiplication photodetector of FIG. 4A.

FIG. 5A illustrates a top view of a waveguide avalanche multiplication photodetector according to a fifth embodiment of the present disclosure, wherein a tapering section of waveguide that is becoming narrower in the y-direction is horizontally disposed at the end of the waveguide layer, and wherein the multiplication layer is in touch with the tapering section of waveguide.

FIG. 5B illustrates a side view of the waveguide avalanche multiplication photodetector of FIG. 5A.

FIG. 6 illustrate a top schematic view of a reflector having a one-dimensional photonic crystal according to an embodiment of the present disclosure.

FIG. 7 illustrate a top schematic view of a reflector having a two-dimensional photonic crystal according to an embodiment of the present disclosure.

FIG. 8 illustrates a top schematic view of the two-dimensional photonic crystal of FIG. 7.

FIG. 9 illustrates a schematic view of a bulk reflector according to an embodiment of the present disclosure.

FIG. 10 illustrates a schematic view of a bulk reflector having a concave reflective surface at a rear end of the bulk reflector, wherein the refractive index of the bulk reflector is the same as that of the waveguide layer or the multiplication layer of a waveguide avalanche multiplication photodetector according to an embodiment of the present disclosure, or wherein the refractive index of the bulk reflector is greater than that of the waveguide layer and that of the multiplication layer of a waveguide avalanche multiplication photodetector according to an embodiment of the present disclosure.

FIG. 11 illustrates a schematic view of a bulk reflector having a concave reflective surface at a front end of the bulk reflector, wherein the refractive index of the bulk reflector is less than that of the waveguide layer and that of the multiplication layer of a waveguide avalanche multiplication photodetector according to an embodiment of the present disclosure.

FIG. 12 illustrates a schematic view of a one-dimensional photonic crystal reflector having a concave reflective surface according to an embodiment of the present disclosure.

FIG. 13 illustrates an elliptic reflective surface of a reflector integrated with a waveguide avalanche multiplication photodetector according to an embodiment of the present disclosure, wherein the elliptic reflective surface has two foci, one of which is located inside the detection section of the waveguide of the waveguide avalanche multiplication photodetector. Arrowed lines therein represent paths of light propagation inside the reflector and the waveguide layer.

FIG. 14A illustrates a top view of the waveguide avalanche multiplication photodetector of FIG. 1 having a one-dimensional photonic crystal reflector.

FIG. 14B illustrates a side view of the waveguide avalanche multiplication photodetector of FIG. 14A.

FIG. 15A illustrates a top view of the waveguide avalanche multiplication photodetector of FIG. 1 having a different one-dimensional photonic crystal reflector.

FIG. 15B illustrates a side view of the waveguide avalanche multiplication photodetector of FIG. 15A.

FIG. 16A illustrates a top view of the waveguide avalanche multiplication photodetector of FIG. 4 having a two-dimensional photonic crystal reflector.

FIG. 16B illustrates a side view of the waveguide avalanche multiplication photodetector of FIG. 16A.

FIG. 17A illustrates a top view of the waveguide avalanche multiplication photodetector of FIG. 2 having a bulk reflector.

FIG. 17B illustrates a side view of the waveguide avalanche multiplication photodetector of FIG. 17A.

FIG. 18A illustrates a top view of the waveguide avalanche multiplication photodetector of FIG. 2 having a different bulk reflector.

FIG. 18B illustrates a side view of the waveguide avalanche multiplication photodetector of FIG. 18A.

### DETAILED DESCRIPTION OF THE PREFERRED EMBODIMENTS

Various exemplary embodiments according to the present disclosure are described in detail hereafter and shown in the drawings. In the description with reference to the drawings, the same reference numbers in the drawings denote elements having a same or similar function, unless otherwise stated. Not all of the possible embodiments consistent with the present disclosure are disclosed herein. Instead, only several non-limiting exemplary embodiments are described hereinafter referring to the system examples according to an aspect of the present disclosure or according to the details described in the attached claims.

The drawings herein, as an integral part of the present disclosure, is intended to illustrate or otherwise demonstrate inventive principles of the present disclosure as applied to the various embodiments disclosed herein. Unless stated otherwise, any mentioning of a physical direction or orientation regarding an embodiment herein is for the convenience of explaining the inventive ideas of the present disclosure in view of the embodiment, rather than limiting the inventive ideas only to the specific direction or orientation mentioned. For example, terms describing a relative physical relationship, such as “upward”, “downward”, “vertical”, “horizontal”, “on top of”, “underneath”, “above”, “below”, “top”, “bottom”, as well as other derivative adjectives, adverbs, or terms, are used with a sole intention to describe features of an embodiment, which may be as shown in the drawings, but not to limit the features to being only so structured or operated in the specific direction or orientation, unless such a limitation is specifically stated in the description.

As one skilled in the art will understand, electronic equipment manufacturers may refer to a component by different names. This document does not intend to distinguish between components that differ in name but not function. In the following description and in the claims, the terms “include”, “comprise” and “have” are used in an open-ended fashion, and thus should be interpreted to mean “include, but not limited to”. Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

When an element or layer is referred to as being “on”, “connected to”, “attached to”, “coupled with” or “interlinked with” another element or layer, it may be directly on or directly connected to the other element or layer, or intervening elements or layers may be presented. Unless stated otherwise, a connection may be a fixed connection wherein the two connected parts do not have a relative movement, or a flexible connection wherein the two connected parts may have a relative movement.

The various embodiments disclosed herein are for the purpose of serving as examples for demonstrating inventive features and benefits of the present disclosure. That is, the inventive principles of the present disclosure are not limited to the applications of the exemplary embodiments. Any application utilizing one of the inventive features described herein, or a combination of a few inventive features thereof, is within the scope of the present disclosure. The scope of the present disclosure is limited only by the claims presented herein.

Although the example embodiments disclosed below are realized with germanium/silicon material system, it is obvious for one with ordinary skills in the art to apply the inventive principles herein to other material systems such as gallium arsenide, indium phosphide, or other III-V semiconductor material systems.

For the ease of describing various features below, a Cartesian coordinate system comprising an x-axis, a y-axis and a z-axis is employed throughout the entire disclosure herein. An x-y plane refers to the plane formed by the x-axis and the y-axis. A y-z plane refers to the plane formed by the y-axis and the z-axis. An x-z plane refers to the plane formed by the x-axis and the z-axis. An x-direction refers to a direction in parallel with the x-axis. A y-direction refers to a direction in parallel with the y-axis. A z-direction refers to a direction in parallel with the z-axis.

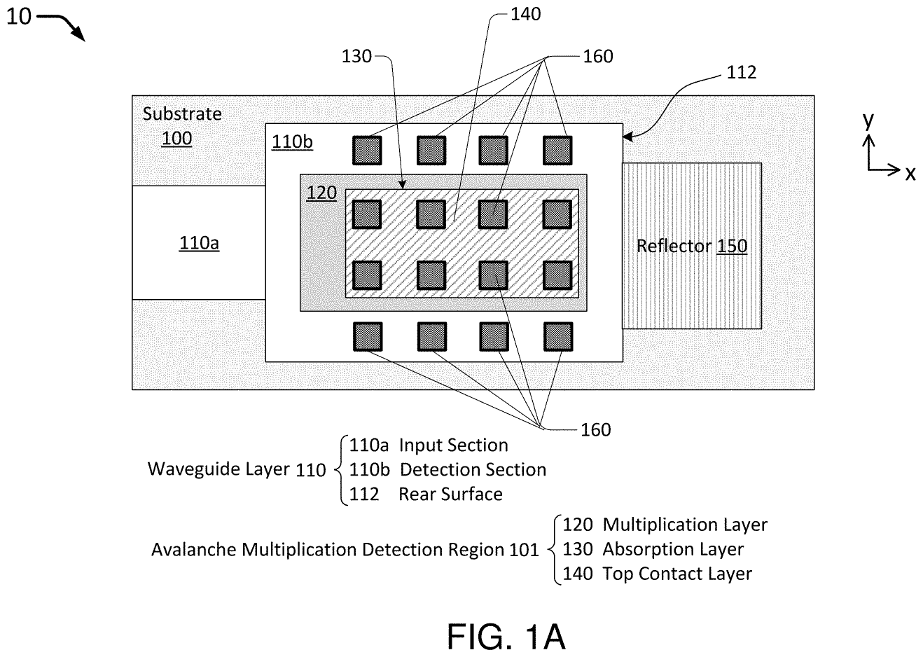

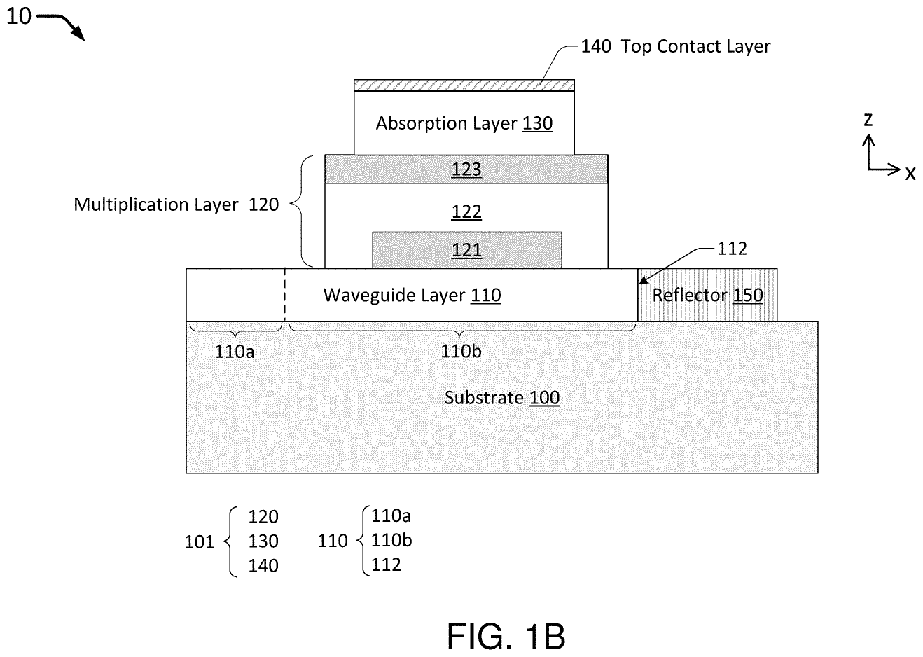

A first embodiment of the present disclosure is illustrated in FIG. 1A and FIG. 1B. Specifically, FIG. 1A illustrates a top view (i.e., parallel to the x-y plane) of a photodetector 10, whereas FIG. 1B illustrates a side view (i.e., parallel to the x-z plane) of the photodetector 10. The photodetector 10 includes a substrate 100, which has a main surface that is perpendicular to the z-axis. Disposed on top of the substrate 100 is a waveguide layer 110, which extends on the main surface of the substrate 100 along the x-direction. The waveguide layer 110 includes an input section 110a and a detection section 110b, which are disposed side by side along the x-direction and adjacent to one another. Namely, the detection section 110b is concatenated with the input section 110a along the x-direction. The detection section 110b is wider (i.e., having a larger dimension in the y-direction) than the input section 110a. The waveguide layer 110 has a rear surface 112 that is located at an end of the detection section 110b opposing the input section 110a. The rear surface 112 is substantially perpendicular to the x-direction. The photodetector 10 also has an avalanche multiplication detection region 101 that is disposed on top of the detection section 110b of the waveguide layer 110. The avalanche multiplication detection region 101 includes a multiplication layer 120, an absorption layer 130, and a top contact layer 140, which are disposed layer by layer and in parallel with the x-y plane as shown in FIG. 1A. Specifically, as shown in FIG. 1B, the multiplication layer 120 is disposed on top of the detection section 110b of the waveguide layer 110, the absorption layer 130 is disposed on top of the multiplication layer 120, and the top contact layer 140 is subsequently disposed on top of the absorption layer 130. The photodetector 10 further includes a reflector 150, which is disposed besides the waveguide layer 110 in the x-direction and adjacent to the rear surface 112 of the waveguide layer 110. The reflector 150 may comprise a one-dimensional photonic crystal or a two-dimensional photonic crystal; alternatively, the reflector 150 may be a bulk reflector comprising a bulk material.

As shown in FIG. 1B, the reflector 150 has substantially a same thickness (i.e., the dimension in the z-direction) as that of the waveguide layer 110. Moreover, the reflector 150 is substantially aligned with the waveguide layer 110 in the z-direction.

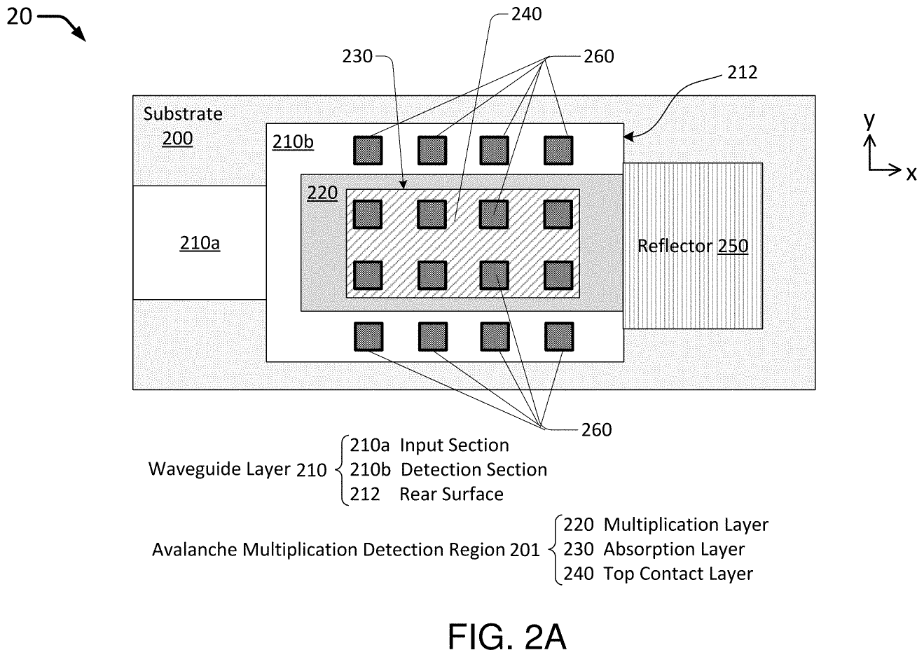

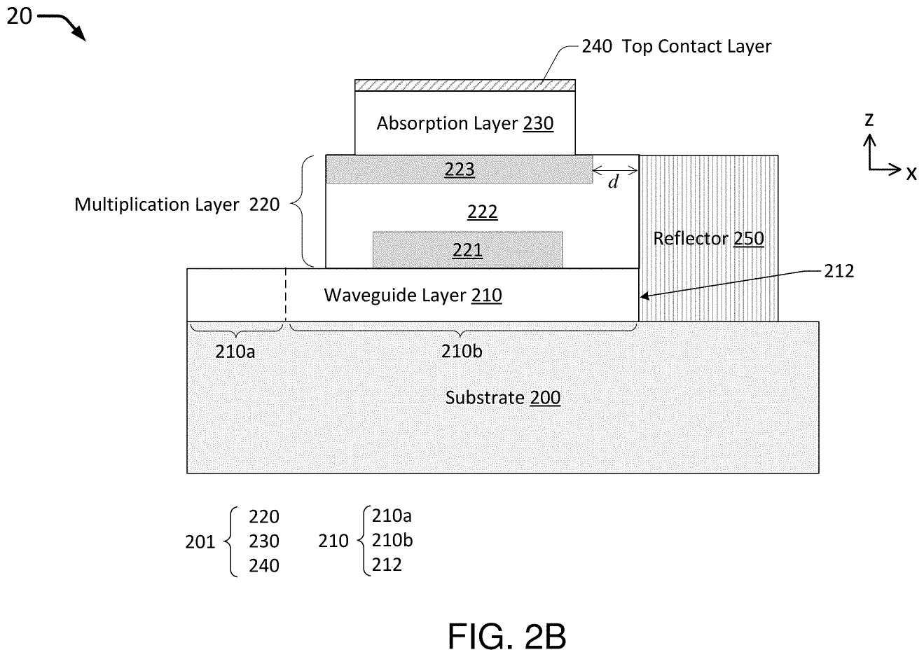

A second embodiment of the present disclosure is illustrated in FIG. 2A and FIG. 2B. Specifically, FIG. 2A illustrates a top view of a photodetector 20, whereas FIG. 2B illustrates a side view of the photodetector 20. The photodetector 20 includes a substrate 200, which has a main surface that is perpendicular to the z-axis. Disposed on top of the substrate 200 is a waveguide layer 210, which extends on the main surface of the substrate 200 along the x-direction. The waveguide layer 210 includes an input section 210a and a detection section 210b, which are disposed side by side along the x-direction and adjacent to one another. Namely, the detection section 210b is concatenated with the input section 210a along the x-direction. The detection section 210b is wider (i.e., having a larger dimension in the y-direction) than the input section 210a. The waveguide layer 210 has a rear surface 212 that is located at an end of the detection section 210b opposing the input section 210a. The rear surface 212 is substantially perpendicular to the x-direction. The photodetector 20 also has an avalanche multiplication detection region 201 that is disposed on top of the detection section 210b of the waveguide layer 210. The avalanche multiplication detection region 201 includes a multiplication layer 220, an absorption layer 230, and a top contact layer 240, which are disposed layer by layer and in parallel with the x-y plane as shown in FIG. 2A. Specifically, as shown in FIG. 2B, the multiplication layer 220 is disposed on top of the detection section 210b of the waveguide layer 210, the absorption layer 230 is disposed on top of the multiplication layer 220, and the top contact layer 240 is subsequently disposed on top of the absorption layer 230. The photodetector 20 further includes a reflector 250, which is disposed besides the waveguide layer 210 and the multiplication layer 220 in the x-direction and adjacent to the rear surface 212 of the waveguide layer 210. The reflector 250 may comprise a one-dimensional photonic crystal or a two-dimensional photonic crystal; alternatively, the reflector 250 may be a bulk reflector comprising a bulk material.

As shown in FIG. 2B, the reflector 250 has substantially a same thickness (i.e., the dimension in the z-direction) as a combination of that of the waveguide layer 210 and that of the multiplication layer 220. Moreover, the reflector 250 is substantially aligned in the z-direction with the combination of the waveguide layer 210 and the multiplication layer 220.

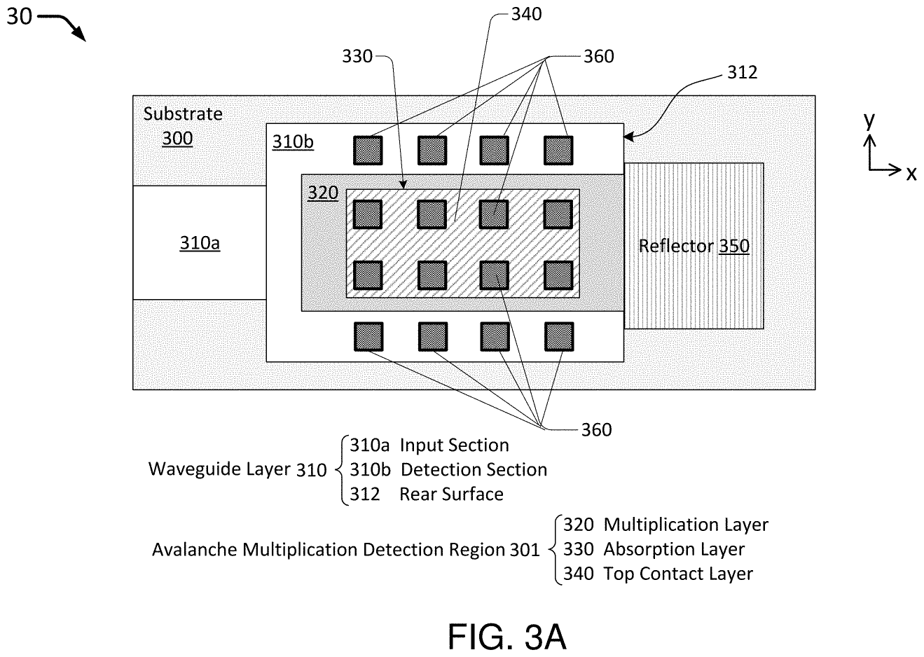

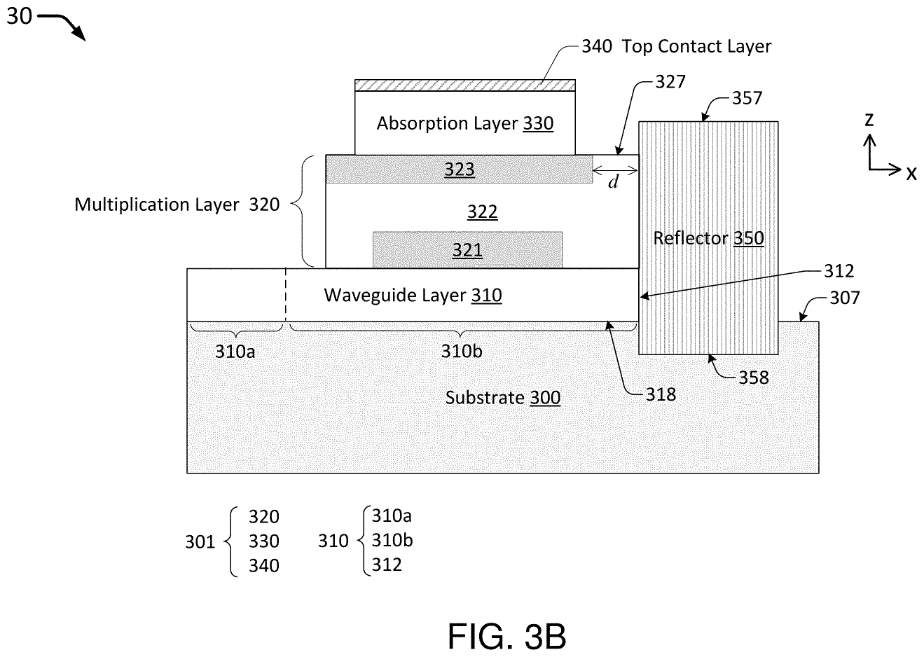

A third embodiment of the present disclosure is illustrated in FIG. 3A and FIG. 3B. Specifically, FIG. 3A illustrates a top view of a photodetector 30, whereas FIG. 3B illustrates a side view of the photodetector 30. The photodetector 30 includes a substrate 300, which has a main surface that is perpendicular to the z-axis. Disposed on top of the substrate 300 is a waveguide layer 310, which extends on the main surface of the substrate 300 along the x-direction. The waveguide layer 310 includes an input section 310a and a detection section 310b, which are disposed side by side along the x-direction and adjacent to one another. Namely, the detection section 310b is concatenated with the input section 310a along the x-direction. The detection section 310b is wider (i.e., having a larger dimension in the y-direction) than the input section 310a. The waveguide layer 310 has a rear surface 312 that is located at an end of the detection section 310b opposing the input section 310a. The rear surface 312 is substantially perpendicular to the x-direction. The photodetector 30 also has an avalanche multiplication detection region 301 that is disposed on top of the detection section 310b of the waveguide layer 310. The avalanche multiplication detection region 301 includes a multiplication layer 320, an absorption layer 330, and a top contact layer 340, which are disposed layer by layer and in parallel with the x-y plane as shown in FIG. 3A. Specifically, as shown in FIG. 3B, the multiplication layer 320 is disposed on top of the detection section 310b of the waveguide layer 310, the absorption layer 330 is disposed on top of the multiplication layer 320, and the top contact layer 340 is subsequently disposed on top of the absorption layer 330. The photodetector 30 further includes a reflector 350, which is disposed besides the waveguide layer 310 and the multiplication layer 320 in the x-direction and adjacent to the rear surface 312 of the waveguide layer 310. The reflector 350 may comprise a one-dimensional photonic crystal or a two-dimensional photonic crystal; alternatively, the reflector 350 may be a bulk reflector comprising a bulk material.

As shown in FIG. 3B, the reflector 350 has a thickness (i.e., the dimension in the z-direction) that is thicker than a combination of that of the waveguide layer 310 and that of the multiplication layer 320. Moreover, the reflector 350 has its top edge 357 higher than the top edge 327 of the multiplication layer 320 in the z-direction. Meanwhile, the reflector 350 has its bottom edge 358 lower than the bottom edge 318 of the waveguide layer 310 in the z-direction. That is, the reflector 350 of photodetector 30 extends beneath the top surface 307 of the substrate 300 in the z-direction.

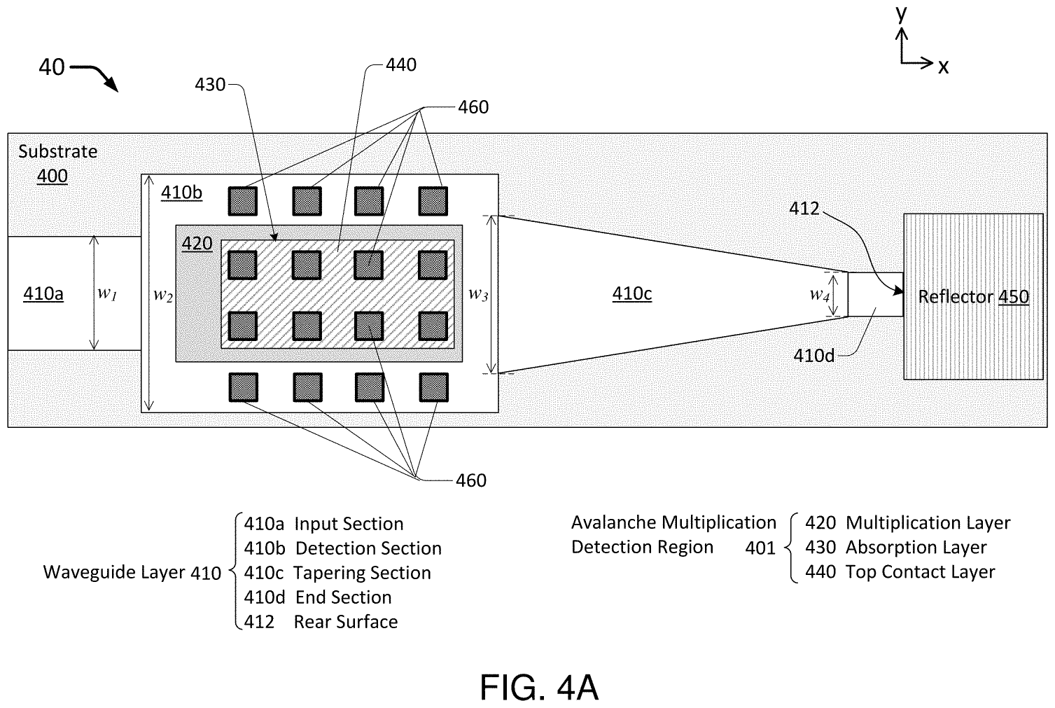

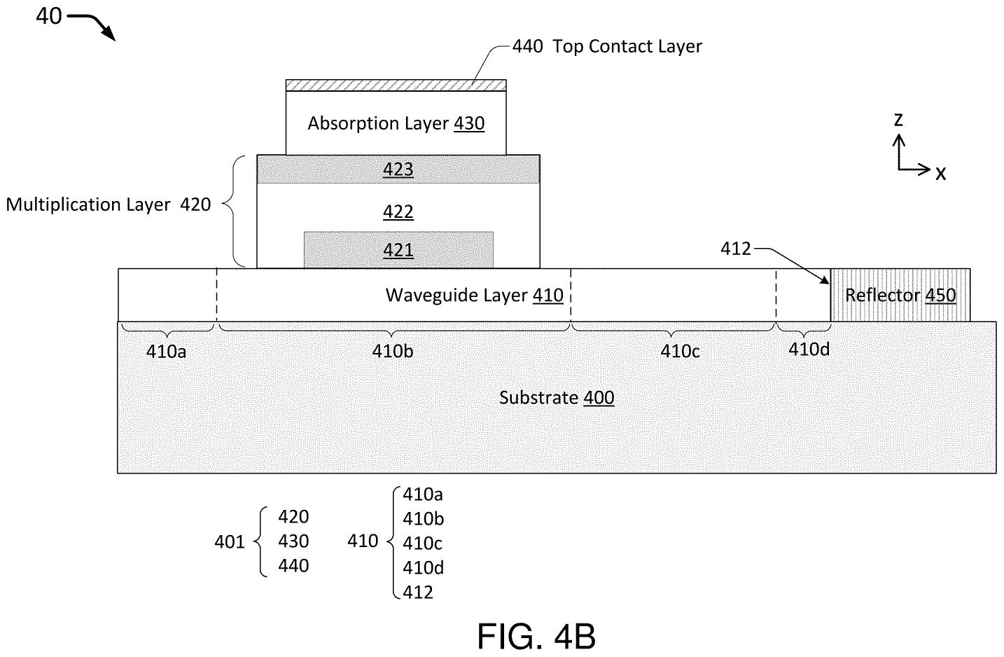

A fourth embodiment of the present disclosure is illustrated in FIG. 4A and FIG. 4B. Specifically, FIG. 4A illustrates a top view of a photodetector 40, whereas FIG. 4B illustrates a side view of the photodetector 40. The photodetector 40 includes a substrate 400, which has a main surface that is perpendicular to the z-axis. Disposed on top of the substrate 400 is a waveguide layer 410, which extends on the main surface of the substrate 400 along the x-direction. The waveguide layer 410 may include three or four sections having different values of width (i.e., the dimension of 410 in the y-direction). As shown in FIG. 4A, the waveguide layer 410 includes an input section 410a having a constant width w₁, a detection section 410b having a constant width w₂, as well as a tapering section 410c having a width that gradually changes from a first width w₃ to a second width w₄ as the tapering section 410c extends away from the detection section 410b in the x-direction. The input section 410a, the detection section 410b, and the tapering section 410c are concatenated one after another along the x-direction, with the detection section 410b disposed between the input section 410a and the tapering section 410c. In some embodiments, the first width w₃ may be larger than the second width w₄, as shown in FIG. 4A, whereas in some alternative embodiments the first width w₃ may be smaller than the second width w₄. In some embodiments, the tapering section 410c may have a width that changes linearly from the first width w₃ to the second width w₄, as shown in FIG. 4A, whereas in some alternative embodiments the width of the tapering section 410c may change from the first width w₃ to the second width w₄ following a hyperbolic or logarithmic profile, or in some other nonlinear fashion. In addition to the input section 410a, the detection section 410b, and the tapering section 410c, the waveguide layer 410 may, as shown in FIG. 4B, optionally include an end section 410d that is concatenated to the tapering section 410c along the x-direction on a side that opposes the detection section 410b. The end section 410 may have a constant width that is substantially the same as the second width w₄ of the tapering section 410c. The waveguide layer 410 has a rear surface 412 that is located at the far end of the waveguide layer 410 opposing the input section 410a thereof. The rear surface 412 is substantially perpendicular to the x-direction. For embodiments wherein the waveguide layer 410 includes the end section 410d, the rear surface 412 is the surface at the end of the end section 410d opposing the input section 410a, as indicated in FIG. 4B. For embodiments wherein the waveguide layer 410 does not include the end section 410d, the rear surface 412 is the surface at the end of the tapering section 410c opposing the input section 410a, i.e., the surface where the tapering section 410c has a width of the second width w₄.

The photodetector 40 also has an avalanche multiplication detection region 401 that is disposed on top of the detection section 410b of the waveguide layer 410. The avalanche multiplication detection region 401 includes a multiplication layer 420, an absorption layer 430, and a top contact layer 440, which are disposed layer by layer and in parallel with the x-y plane as shown in FIG. 4A. Specifically, as shown FIG. 4B, the multiplication layer 420 is disposed on top of the detection section 410b of the waveguide layer 410, the absorption layer 430 is disposed on top of the multiplication layer 420, and the top contact layer 440 is subsequently disposed on top of the absorption layer 430. The photodetector 40 further includes a reflector 450, which is disposed besides the waveguide layer 410 in the x-direction and adjacent to the rear surface 412 of the waveguide layer 410. The reflector 450 may comprise a one-dimensional photonic crystal or a two-dimensional photonic crystal; alternatively, the reflector 450 may be a bulk reflector comprising a bulk material.

The tapering section 410c provides at least two benefits to the operation of the photodetector 40. Firstly, with the inclusion of the tapering section 410c, the waveguide layer allows the reflector 450 to be moved to a location that is physically farther away from the avalanche multiplication detection region 401. The far-away location reduces the amount of undesired scattered optical signals scattered by the reflector 450, which are unavoidable due to manufacturing imperfection of the reflector 450, that enters the avalanche multiplication detection region 401. Secondly, the tapering shape of the tapering section 410c is able to inhibit or otherwise filter out higher-order propagation modes of the optical signal propagated in the waveguide layer 410. The higher-order propagation modes are undesirable as they adversely affect the response time of the photodetector 40, thereby reducing the operation speed thereof.

As shown in FIG. 4B, the reflector 450 has substantially a same thickness (i.e., the dimension in the z-direction) as that of the waveguide layer 410. Moreover, the reflector 450 is substantially aligned with the waveguide layer 410 in the z-direction.

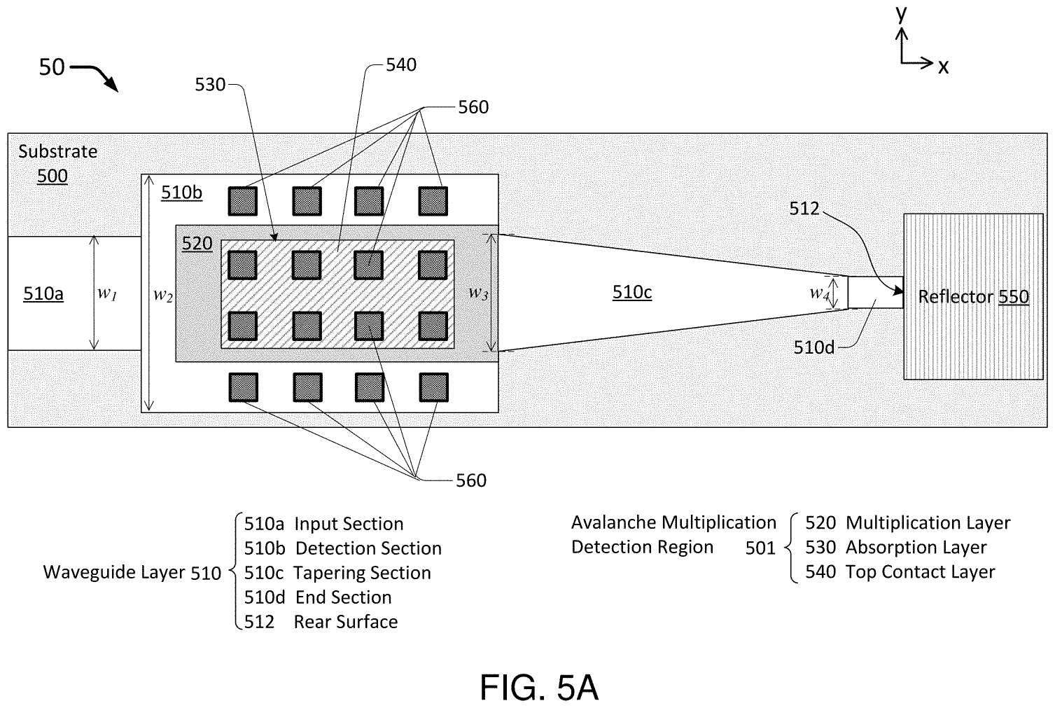

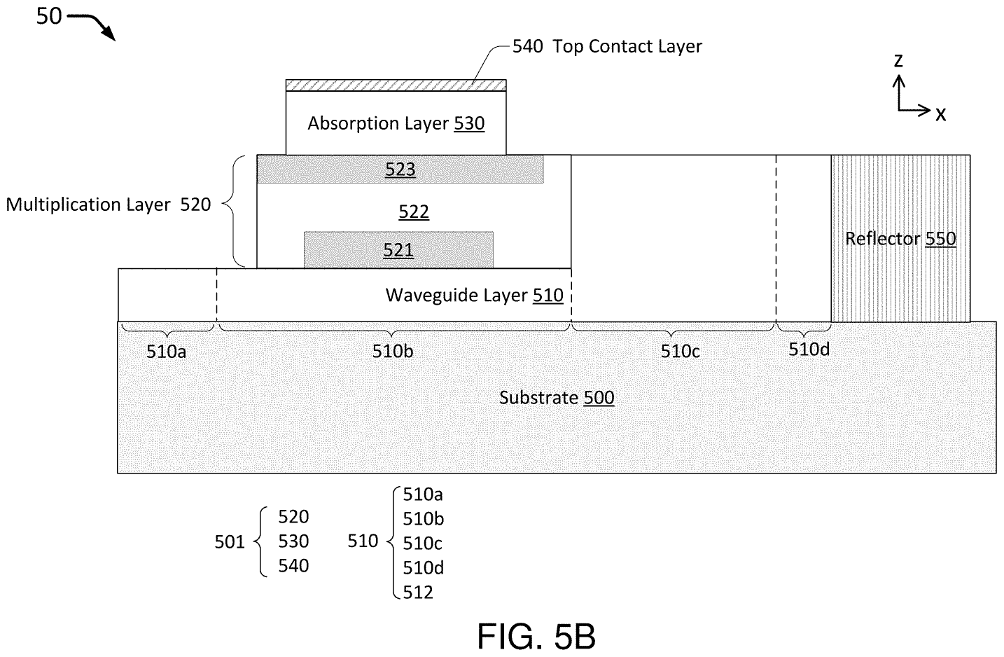

A fifth embodiment of the present disclosure is illustrated in FIG. 5A and FIG. 5B. Specifically, FIG. 5A illustrates a top view of a photodetector 50, whereas FIG. 5B illustrates a side view of the photodetector 50. The photodetector 50 includes a substrate 500, which has a main surface that is perpendicular to the z-axis. Disposed on top of the substrate 500 is a waveguide layer 510, which extends on the main surface of the substrate 500 along the x-direction. The waveguide layer 510 may include three or four sections having different values of width (i.e., the dimension of 510 in the y-direction). As shown in FIG. 5A, the waveguide layer 510 includes an input section 510a having a constant width w₁, a detection section 510b having a constant width w₂, as well as a tapering section 510c having a width that gradually changes from a first width w₃ to a second width w₄ as the tapering section 510c extends away from the detection section 510b in the x-direction. The input section 510a, the detection section 510b, and the tapering section 510c are concatenated one after another in the x-direction, with the detection section 510b disposed between the input section 510a and the tapering section 510c. In some embodiments, the first width w₃ may be larger than the second width w₄, as shown in FIG. 5A, whereas in some alternative embodiments the first width w₃ may be smaller than the second width w₄. In some embodiments, the tapering section 510c may have a width that changes linearly from the first width w₃ to the second width w₄, as shown in FIG. 5A, whereas in some alternative embodiments the width of the tapering section 510c may change from the first width w₃ to the second width w₄ following a hyperbolic or logarithmic profile, or in some other nonlinear fashion. In addition to the input section 510a, the detection section 510b, and the tapering section 510c, the waveguide layer 510 may, as shown in FIG. 5B, optionally include an end section 510d that is concatenated to the tapering section 510c on a side that opposes the detection section 510b. The end section 510 may have a constant width that is substantially the same as the second width w₄ of the tapering section 510c. The waveguide layer 510 has a rear surface 512 that is located at the far end of the waveguide layer 510 opposing the input section 510a thereof. For embodiments wherein the waveguide layer 510 includes the end section 510d, the rear surface 512 is the surface at the end of the end section 510d opposing the input section 510a, as indicated in FIG. 5B. For embodiments wherein the waveguide layer 510 does not include the end section 510d, the rear surface 512 is the surface at the end of the tapering section 510c opposing the input section 510a, i.e., the surface where the tapering section 510c has a width of the second width w₄.

The photodetector 50 also has an avalanche multiplication detection region 501 that is disposed on top of the detection section 510b of the waveguide layer 510. The avalanche multiplication detection region 501 includes a multiplication layer 520, an absorption layer 530, and a top contact layer 540, which are disposed layer by layer and in parallel with the x-y plane as shown in FIG. 5A. Specifically, as shown FIG. 5B, the multiplication layer 520 is disposed on top of the detection section 510b of the waveguide layer 510, the absorption layer 530 is disposed on top of the multiplication layer 520, and the top contact layer 540 is subsequently disposed on top of the absorption layer 530. The photodetector 50 further includes a reflector 550, which is disposed besides the waveguide layer 510 in the x-direction and adjacent to the rear surface 512 of the waveguide layer 510. The reflector 550 may comprise a one-dimensional photonic crystal or a two-dimensional photonic crystal; alternatively, the reflector 550 may be a bulk reflector comprising a bulk material.

As shown in FIG. 5B, each of the tapering section 510c and the end section 510d has substantially a same thickness (i.e., the dimension in the z-direction) as a combination of that of the detection section 510b and that of the multiplication layer 520. In addition, the reflector 550 has substantially a same thickness (i.e., the dimension in the z-direction) as that of the tapering section 510c. Moreover, the reflector 550 is substantially aligned in the z-direction with the combination of the waveguide layer 510 and the multiplication layer 520. Moreover, the reflector 550 is substantially aligned in the z-direction with the tapering section 510c and the end section 510d.

As illustrated in each of the embodiments above, the technical solutions of the present disclosure greatly reduce the structural complexity of photodetector design, especially that of the reflectors therein. The semiconductor processing technology utilized for making the photodetectors of the present disclosure is generally compatible with existing CMOS technologies and without a need for additional processing steps or a great increase in technology complexity, thereby achieving a reduced manufacturing cost. The employment of a reflector, such as one of the reflectors 150, 250, 350, 450 and 550, enables an enhanced responsivity of the photodetector, which spares a need for a longer waveguide that would have disadvantageously increased the junction capacitances thereof. Accordingly, the unique designs of the photodetectors of the present disclosure allows for achieving a high responsivity as well as a high operation speed at the same time.

The photodetectors 10, 20, 30, 40 and 50 may employ similar semiconductor materials for the substrates, the avalanche multiplication detection regions, and the waveguide layers thereof. For example, each of the substrates 100, 200, 300, 400 and 500 may comprise a silicon substrate having a silicon dioxide top layer. The silicon dioxide top layer is preferred to have a thickness larger than one micrometer (μm), whereas the silicon substrate does not have a required thickness in specific. Alternatively, each of the substrates 100, 200, 300, 400 and 500 may comprise a pure silicon substrate, and the waveguide layer (i.e., each of the waveguide layers 110, 210, 310, 410 and 510) may be formed by etching a certain depth into the pure silicon substrate from its top surface.

For each of the photodetectors 10, 20, 30, 40 and 50, the detection section of the waveguide layer (i.e., the detection section 110b, 210b, 310b, 410b, or 510b) is an N+ doped region that is heavily doped by an N-type dopant with a doping concentration higher than 1e18 per cubic centimeter (cm⁻³).

Each of the multiplication layers 120, 220, 320, 420 and 520 comprises silicon that is doped with a respective doping profile. Take the multiplication layer 120 of the photodetector 10 for example. As shown in FIG. 1B, the multiplication layer 120 includes an N-doped region 121, a P-doped region 123, and a remaining region 122 that is either undoped or lightly doped. The N-doped region 121 is located at the bottom of the multiplication layer 120 and adjacent to the detection section 110b of the waveguide layer 110, whereas the P-doped region 123 is located on the top portion of the multiplication layer 120, adjacent to the absorption layer 130. In an event that the region 122 is lightly doped, the dopants thereof can be either N-type or P-type. The multiplication layers 120, 220, 320, 420 and 520 have similar doping profiles. Similar to the multiplication layer 120, the multiplication layers 220, 320, 420 and 520 have N-doped regions 221, 321, 421 and 521, respectively, as well as P-doped regions 223, 323, 423 and 523, respectively. The remaining area of the multiplication layers 220, 320, 420 and 520, namely, regions 222, 322, 422 and 522, are either undoped silicon, or lightly doped with either N-type or P-type dopants. A limitation worth noting regarding the P-doped regions 123, 223, 323, 423 and 523 resides in the distance from the respective reflectors 150, 250, 350, 450 and 550. Specifically, in an event that the reflector of a photodetector comprises a metal material, the P-doped region of the photodetector is required to be separated from the metal reflector by at least a predefined minimum distance. For example, as shown in FIG. 2B, in an event that the reflector 250 is a metal reflector, the P-doped region 223 of the photodetector 20 is required to be separated from the reflector 250 by a distance d that is 1 μm or more. That is, the P-doped region 223 is not allowed to cover the entire length of the multiplication layer 220 in the x-direction if the reflector 250 is a metal reflector. The width (i.e., the dimension in the y-direction) of the P-doped region 223 is, on the other hand, not subjected to such a limitation. That is, regardless whether or not the reflector 250 is a metal reflector, the P-doped region 223 can cover either the entire width of the multiplication layer 220, or a portion of the multiplication layer 220 in the y-direction. Same can be said of the photodetector 30. As shown in FIG. 3B, in an event that the reflector 350 is a metal reflector, the P-doped region 323 is required to be separated from the reflector 350 by a predefined distance d. In some embodiments, the predefined minimum distance d may be 1 μm. Similarly, there is no limitation as to the dimension of the P-doped region 323 in the y-direction regardless of the reflector 350 being metal or non-metal.

Each of the absorption layers 130, 230, 330, 430 and 530 may be made of material comprising germanium, silicon-germanium alloy, silicon quantum dots, silicon-germanium quantum dots, or germanium quantum dots. In an event that an absorption layer comprises silicon-germanium alloy, germanium should be more than 50% in composition of the silicon-germanium alloy. Each of the absorption layer 130, 230, 330, 430 and 530 may be undoped, or lightly doped with P-type dopants at a doping concentration less than 1e18 cm⁻³.

Each of the top contact layers 140, 240, 340, 440 and 540 is a P+ doped region that is heavily doped with P-type dopants at a doping concentration greater than 1e19 cm⁻³. In some embodiments, each of the top contact layers 140, 240, 340, 440 and 540 may be formed by heavily doping the respective absorption layer 130, 230, 330, 430 or 530 to a predetermined depth from the top of the respective absorption layer with the P-type dopants at the doping concentration greater than 1e19 cm⁻³. In some alternative embodiments, each of the top contact layers 140, 240, 340, 440 and 540 may be formed by firstly depositing a layer of polysilicon on top of the respective absorption layer 130, 230, 330, 430 or 530, followed by heavily doping the layer of polysilicon with the P-type dopants at the doping concentration greater than 1 el 9 cm⁻³.

Photodetectors 10, 20, 30, 40 and 50 further have metal contact electrodes such as metal contacts 160, 260, 360, 460 and 560 as respectively shown in FIGS. 1A-5A. The metal contacts 160, 260, 360, 460 and 560 may be formed with materials such as tungsten, copper, or aluminum.

The P-type dopants for forming various layers mentioned above may be boron, whereas the N-type dopants for forming various layers mentioned above may be arsenic or phosphor. A dopant concentration of a P-doped region is supposed to be less than that of a P+ doped region, whereas a dopant concentration of an N-doped region is supposed to be less than that of an N+ doped region. In general, each of an N-doped region and a P-doped region may have a doping concentration in a range of 1e16-5e18 cm⁻³. A doping concentration of any region as stated in the present disclosure refers to a peak doping concentration of the region. This is because the doping concentration of any region is practically a distribution rather than a constant value. Therefore, when it is stated herein that a doping concentration of a region or a layer is to be greater or less than a certain value, it is to be interpreted that the peak value of the doping concentration within the region or the layer is to be greater or less than the certain value.

It is obvious to one skilled in the art that the doping types of regions or layers (i.e., whether a region or layer is P-type or N-type) in the various embodiments disclosed above are interchangeable. That is, a valid embodiment is easily achieved by changing all P-type layers/regions to N-type and all N-type layers/regions to P-type in any of the embodiments disclosed above.

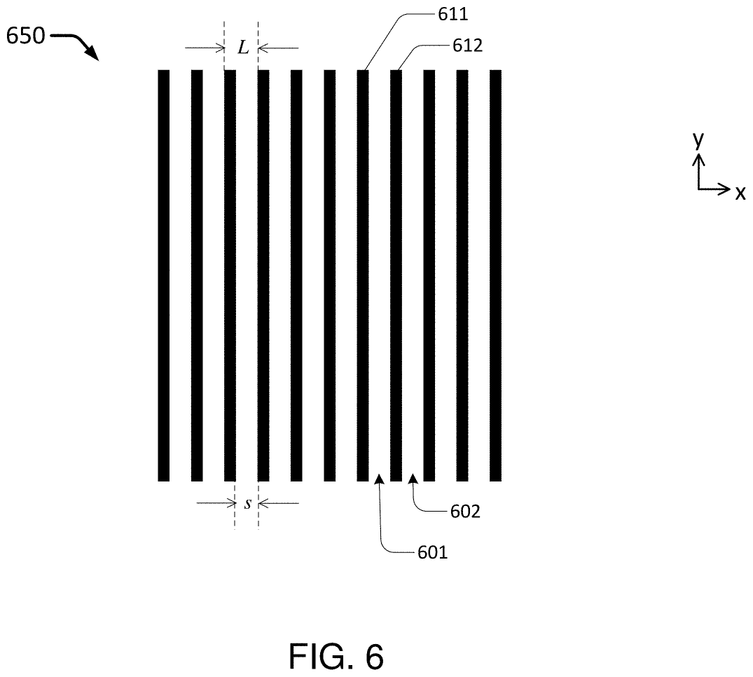

In some embodiments, any of the reflectors 150, 250, 350, 450 and 550 may be realized by a one-dimensional photonic crystal, which is sometimes referred as an optical grating. A reflector (e.g., the reflector 150, 450 or 550) having a one-dimensional photonic crystal may be formed by etching the waveguide layer (e.g., the waveguide layer 110, 410 or 510) to form a plurality of one-dimensional grooves that are periodically arranged. Alternatively, the one-dimensional grooves may be etched in both the waveguide layer (e.g., the waveguide layer 210) and the multiplication layer (e.g., the multiplication layer 220) to form the reflector (e.g., the reflector 250) having the one-dimensional photonic crystal. A top view of a one-dimensional photonic crystal 650 is illustrated in FIG. 6, wherein the darker stripes of FIG. 6 represent un-etched material called “teeth” (e.g., teeth 611 and 612), and the area in between the darker stripes are the grooves (e.g., grooves 601 and 602) that are etched away. In some embodiments, the grooves may be filled with silicon dioxide. In some alternative embodiments, the grooves may be filled with silicon nitride, silicon oxynitride, or some other material having a refractive index lower than that of the teeth. In some embodiments the etched grooves of the one-dimensional photonic crystal 650 may penetrate the waveguide layer, but this is not so required, as the one-dimensional photonic crystal 650 will still function as a reflector even though the etched grooves do not penetrate the waveguide layer. The period of the of a one-dimensional photonic crystal 650, indicated as L in FIG. 6, is supposed to be within a range of 0.5λ-10λ, whereas A represents the wavelength of the optical signal detected by the photodetector as the optical signal travels within the waveguide layer. For example, an optical signal having a wavelength of 1310 nanometer (nm) in vacuum travels in silicon with a wavelength of 378 nm. Namely, for the optical signal traveling in a waveguide layer (e.g., the waveguide layer 110) made of silicon, λ=378 nm. It follows that the period L of the one-dimensional photonic crystal of the corresponding reflector (e.g., the reflector 150) will be in the range of 189 nm<L<3780 nm. Moreover, it is required that the width of each of the grooves of the one-dimensional photonic crystal 650, indicated as s in FIG. 6, needs to be between 0.1× and 0.9× of the period L. Namely, the one-dimensional photonic crystal 650 is required to have a duty cycle in a range of 0.1-0.9, wherein the duty cycle of the one-dimensional photonic crystal 650 is defined as a ratio s/L, i.e., the ratio of the groove width, s, to the grating period, L. It is worth noting that a one-dimensional photonic crystal may still function as a reflector even if L<0.5λ. However, a one-dimensional photonic crystal having L<0.5λ may result in a low reflectivity as a reflector, not to mention that it is often difficult to realize such a one-dimensional photonic crystal using current semiconductor processing technologies.

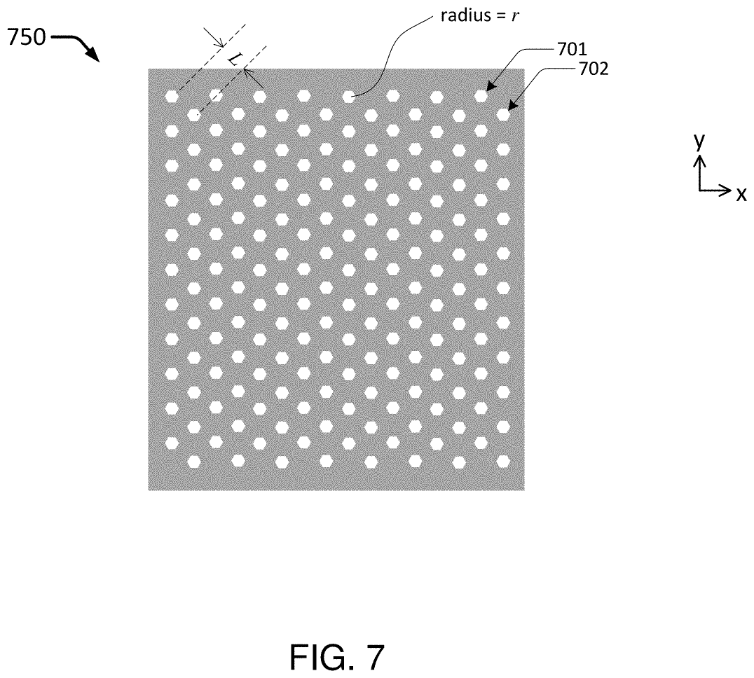

In some embodiments, any of the reflectors 150, 250, 350, 450 and 550 may be realized by a two-dimensional photonic crystal, such as a two-dimensional photonic crystal 750, a top view of which is illustrated in FIG. 7. A reflector (e.g., the reflector 150, 450 or 550) having a two-dimensional photonic crystal may be formed by etching the waveguide layer (e.g., the waveguide layer 110, 410 or 510) to form a two-dimensional array of holes or columns that are periodically arranged. For example, each of instances 701 and 702 may be a hole or a column of the two-dimensional photonic crystal 750. In an event that columns are used, the columns are to be substantially aligned along the z-direction. Alternatively, the two-dimensional array of holes or columns may be formed in both the waveguide layer (e.g., the waveguide layer 210) and the multiplication layer (e.g., the multiplication layer 220) to realize the reflector (e.g., the reflector 250) having the two-dimensional photonic crystal. As shown in FIG. 7, the darker area represents the material that is etched away, and each of the white dots represents a hole, or a column that extends along the z-direction. In some embodiments the columns of the two-dimensional photonic crystal 750 that are formed due to the etching process may amount to the entire thickness of the waveguide layer (i.e., the dimension of the waveguide layer in the z-direction), but this is not so required, as the two-dimensional photonic crystal 750 will still function as a reflector even though the exposed columns do not amount to the entire thickness of the waveguide layer. The period of the of a two-dimensional photonic crystal 750, such as the one indicated as L in FIG. 7, is supposed to be within a range of 0.5λ-10λ, whereas A represents the wavelength of the optical signal detected by the photodetector as the optical signal travels within the waveguide layer. An aspect ratio, r/L, may be defined for the two-dimensional photonic crystal 750, wherein r represents the radius of the cross-sectional circle of each of the columns in an event that the columns are circular cylinders. In an event that the columns are elliptic cylinders, r is calculated as the average of the two semi-axes of the base ellipse of the elliptic cylinders. It is required that the aspect ratio, r/L, be in a range of 0.1-0.45 for the two-dimensional photonic crystal 750.

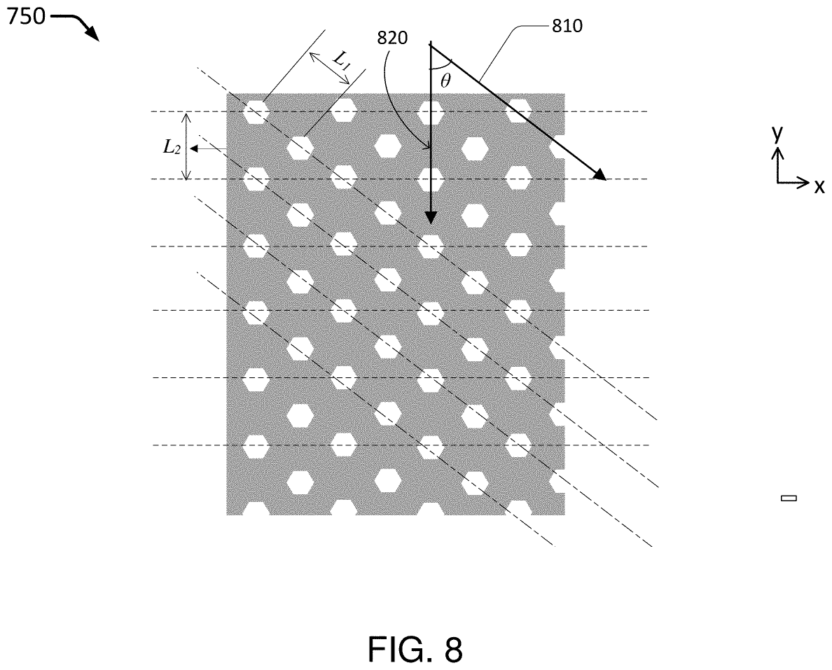

The two-dimensional photonic crystal mentioned above is composed of a two-dimensional array of physical structures and thus has two or more fundamental directions. FIG. 8 illustrates a portion of the two-dimensional photonic crystal 750, along with two fundamental directions 810 and 820 of the two-dimensional photonic crystal 750. The two fundamental directions 810 and 820 are at an angle of θ from one another, and each of the two fundamental directions 810 and 820 possesses a corresponding period, respectively indicated by L₁ and L₂ in FIG. 8. That is, the columns of the two-dimensional photonic crystal 750 are periodically arranged with the period L₁ in the fundamental direction 810, whereas the columns of the two-dimensional photonic crystal 750 are periodically arranged with the period L₂ in the fundamental direction 820. In practical applications, the angle θ between the two fundamental directions 810 and 820 is commonly chosen to be either 90 (i.e., a tetragonal structure) or 60 degrees (i.e., a hexagonal structure). Also, the periods L₁ and L₂ are often chosen to be equal in many embodiments, although in some other embodiments the periods L₁ and L₂ may be made unequal.

In an event that any of the reflectors 150, 250, 350, 450 and 550 is realized by a one-dimensional or two-dimensional photonic crystal, the period of the photonic crystal may be designed such that the optical wavelength of the optical signal to be detected by the respective photodetector is within the first photonic bandgap (i.e., the photonic bandgap having the lowest energy) of the respective reflector. For example, fora photodetector detecting an optical signal having a 1550 nm vacuum wavelength, examples of a suitable reflector may be: (1) a one-dimensional photonic crystal having a period of 474 nm and a duty cycle of 0.65, thus exhibiting a first photonic bandgap of 1.28-2.03 μm; or (2) a two-dimensional photonic crystal having a hexagonal structure with a period of 474 nm and an aspect ratio of 0.35, thereby exhibiting a first photonic bandgap of 1.39-1.70 μm. In either case, the chosen period and the duty cycle or the aspect ratio of the photonic crystal both fulfill the requirements disclosed above.

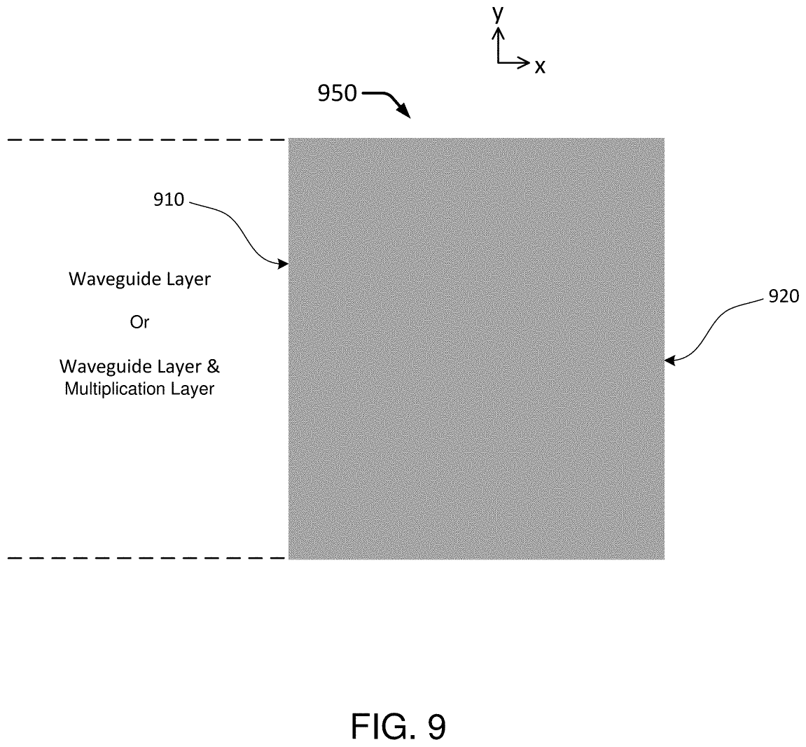

In some embodiments, any of the reflectors 150, 250, 350, 450 and 550 may be a bulk reflector comprising a bulk material. FIG. 9 illustrates a schematic view of a bulk reflector 950. In an event that both the waveguide layer (e.g., the waveguide layer 110, 210, 310, 410 or 510) and the multiplication layer (e.g., the multiplication layer 120, 220, 320, 420 or 520) are silicon, the corresponding reflector (e.g., the reflector 150, 250, 350, 450 or 550) comprising the bulk reflector 950 may be made of material having a higher-than-silicon refractive index (e.g., hafnium dioxide), material having a lower-than-silicon refractive index (e.g., silicon dioxide, silicon nitride, or silicon oxynitride), or metal (e.g., tungsten, copper, or aluminum). In some embodiments, the bulk reflector 950 may be made of air. That is, the reflectors 150, 250, 350, 450 and 550 may simply be removed from the photodetectors 10, 20, 30, 40 and 50, respectively, and no specific material but air is used in its place. In other words, air is used in the embodiments to serve as a low-refractive-index material that provides a function of partial reflection.

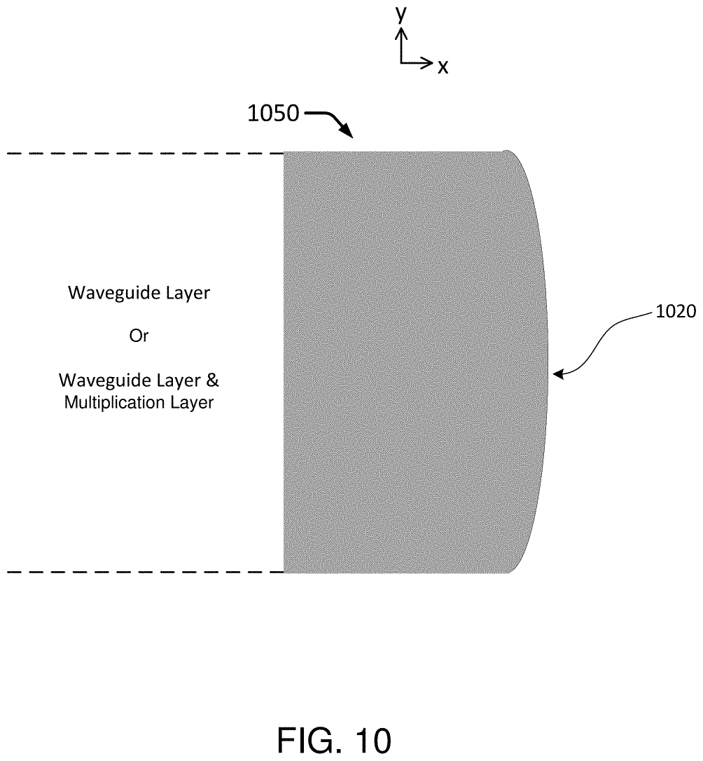

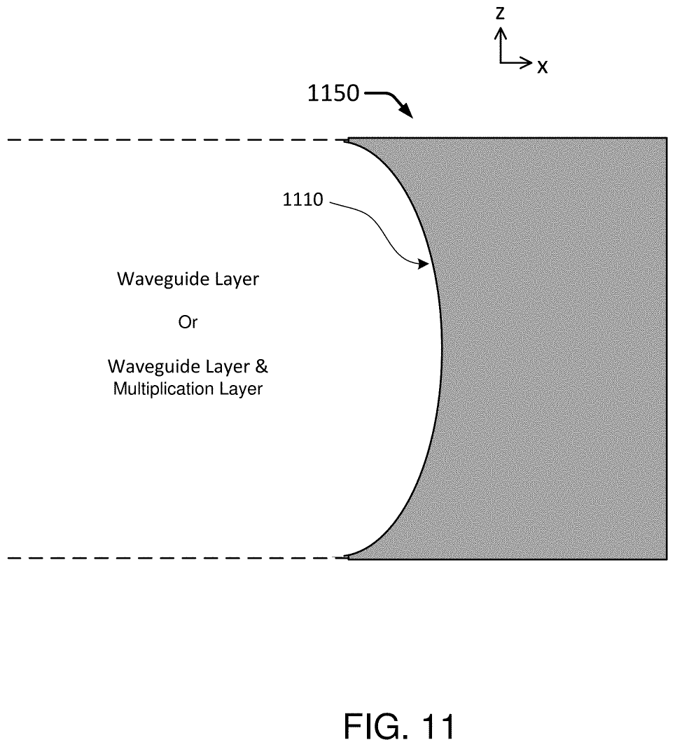

The bulk reflector 950 may have one or more reflective surfaces that are substantially parallel with the z-axis for reflecting optical signals propagating through the waveguide layer. In some embodiments, the reflective surfaces of the bulk reflector 950 may be flat, such as reflective surfaces 910 and 920 of FIG. 9, which are parallel to the y-z plane. In some other embodiments, one or more of the reflective surfaces may not be flat, and may have a curvature. For example, the bulk reflector 1050 of FIG. 10 has a curved or otherwise concave reflective rear surface 1020 located at the rear end of the bulk reflector 1050 (i.e., the end of the bulk reflector 1050 opposing the waveguide layer, corresponding to the reflective surface 920 of FIG. 9), wherein the concave reflective rear surface is substantially parallel to the z-axis. The refractive index of the bulk reflector 1050 is greater than or equal to that of the waveguide layer preceding the bulk reflector 1050. In some embodiments wherein the bulk reflector has a refractive index less than that of the waveguide layer, the bulk reflector may have a curved reflective surface at the front end of the bulk reflector (i.e., the end of the bulk reflector adjacent to the waveguide layer, corresponding to the reflective surface 910 of FIG. 9). FIG. 11 illustrates a schematic view of a bulk reflector 1150 having a concave reflective surface 1110 at a front end of the bulk reflector 1150, wherein the refractive index of the bulk reflector 1150 is less than that of the waveguide layer and that of the multiplication layer, wherein the waveguide layer, and in some cases the multiplication layer too, are adjacent to the bulk reflector 1150. In an event that the reflective surfaces are flat (e.g., the reflective surfaces 910 and 920), it matters little where the exact locations of the reflective surfaces are. Moreover, as long as the bulk reflector 950 has a different refractive index than that of either the waveguide layer or the multiplication layer, the front surface 910 is reflective. On the other hand, the rear surface 920 is always reflective.

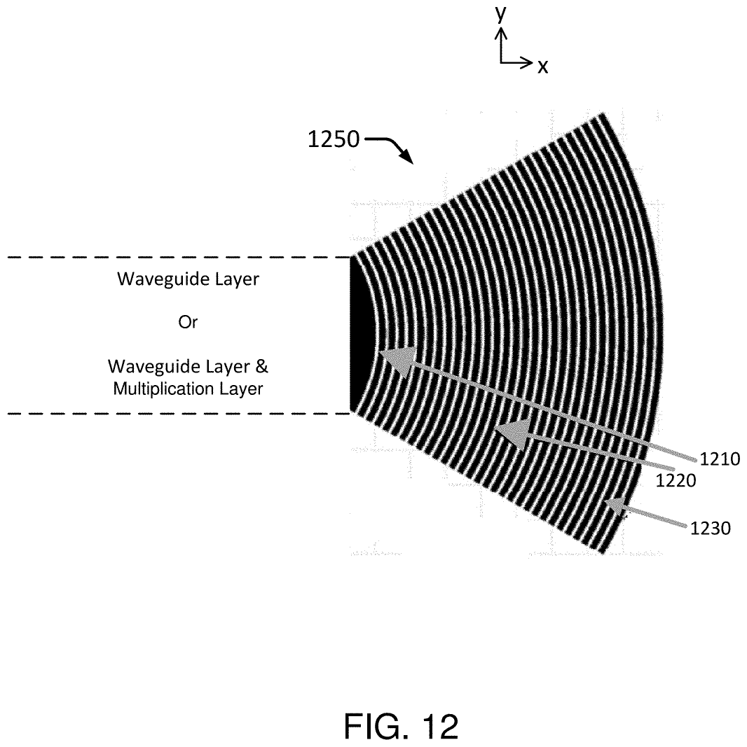

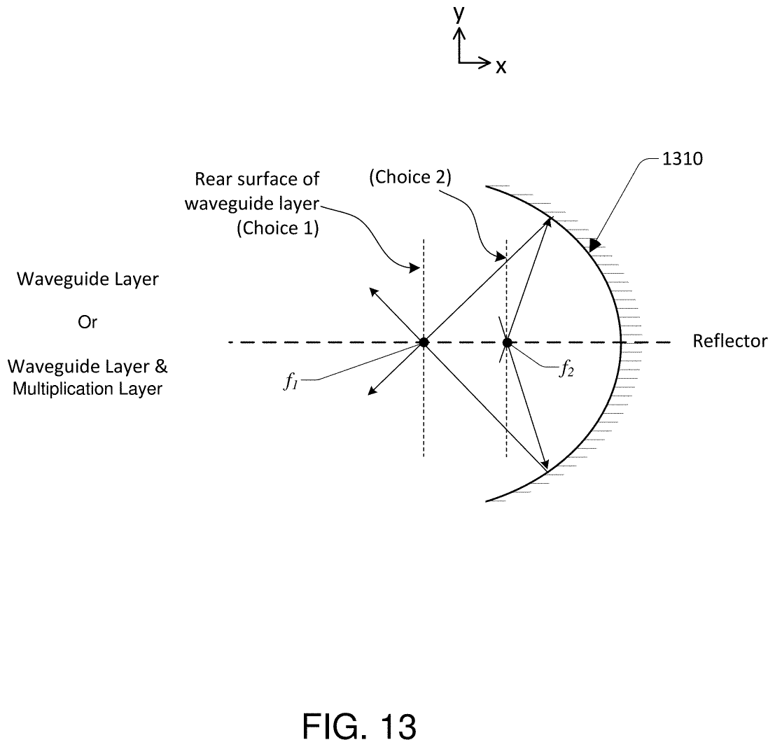

The one-dimensional and two-dimensional photonic crystals disclosed above, such as the one-dimensional photonic crystal 650 and the two-dimensional photonic crystal 750, generally have flat reflective surfaces. Nevertheless, in some alternative embodiments, any of the reflectors 150, 250, 350, 450 and 550 may be realized by a one-dimensional or two-dimensional photonic crystal that effectively constitutes a curved reflective surface. For example, FIG. 12 illustrates a schematic view of a one-dimensional photonic crystal reflector 1250 having a concave reflective surface that is collectively realized by a plurality of periodically repeated curved grooves of the photonic crystal, such as curved grooves 1210, 1220 and 1230. The plurality of curved grooves of FIG. 12 may be elliptic curves sharing a same set of foci, parabolic curves sharing a same focus, circular curves sharing a same focus, or other kinds of concave curves having a focusing effect. In an event that the plurality of curved grooves of FIG. 12 are elliptic, there may be two choices for placing the photonic crystal reflector 1250 relative to the waveguide layer. The two choices can be described with FIG. 13. FIG. 13 illustrates an elliptic reflective surface 1310 that may be collectively formed by the various curved grooves of the one-dimensional photonic crystal reflector 1250. When employed by any of the photodetectors 10, 20, 30, 40 and 50 as the respective reflector, the elliptic reflective surface 1310 is concave towards the waveguide layer of the photodetector. As shown in FIG. 13, the elliptic reflective surface 1310 has two foci, f₁ and f₂. The first focus f₁ is the focus that is farther away from the elliptic reflective surface 1310, while the second focus f₂ is the focus that is closer to the elliptic reflective surface 1310. Arrowed lines of FIG. 13 represent paths of optical signal propagating inside the reflector and the waveguide layer. A first choice for placing the waveguide layer (e.g., the waveguide layer 110, 210, 310, 410 or 510) relative to the photonic crystal reflector 1250 is to align the rear surface of the respective waveguide layer, i.e., the rear surface 112, 212, 312, 412 or 512, with the focus f₁. That is, place the photonic crystal reflector 1250 such that the focus f₁ is located on the rear surface of the waveguide layer. A second choice for placing the waveguide layer relative to the photonic crystal reflector 1250 is to align the rear surface of the respective waveguide layer with the focus f₂. That is, place the photonic crystal reflector 1250 such that the focus f₂ is located on the rear surface of the waveguide layer. With the second choice, it is preferable that the focus f₁ is meanwhile located within the detection section of the waveguide layer. Namely, the photonic crystal reflector 1250 is to be designed carefully such that when the focus f₂ is located on the rear surface of the waveguide layer (e.g., the rear surface 112, 212, 312, 412 or 512), the focus f₁ is located within the detection section (e.g., the detection section 110b, 210b, 310b, 410b or 510b) of the waveguide layer.

Regardless whether the reflector is embodied by a one-dimensional photonic crystal, a two-dimensional photonic crystal, or a bulk reflector, as long as the reflector possesses or otherwise effectively constitutes a concave reflective surface, it is required that the concave reflective surface has at least one focus located at the rear surface of the waveguide layer (e.g., the rear surface 112, 212, 312, 412 or 512) or within the detection section of the waveguide layer (e.g., the detection section 110b, 210b, 310b, 410b or 510b). The only exception is if the waveguide layer includes a tapering section (e.g., the tapering section 410c), in which case it is acceptable if at least one focus of the concave reflective surface is located within the tapering section. For example, in an event that the reflector 450 possesses or otherwise effectively constitutes a concave reflective surface, it is required that the concave reflective surface of the reflector 450 has at least one focus located at the rear surface 412 of the waveguide layer 410 or within the tapering section 410c of the waveguide layer 410.

In general, each of the waveguide layers 110, 210, 310, 410 and 510 has a longitudinal axis that is substantially perpendicular to the y-z plane, whereas each of the reflectors 150, 250, 350, 450 and 550 provides a reflective surface that is substantially parallel with the y-z plane. Namely, in an event that the reflector comprises a photonic crystal, each of the grooves, holes, or columns of the photonic crystal should have its sidewall or sidewalls substantially parallel with the y-z plane, with a tolerance of about plus or minus 10 degrees (+1-10°). That is, as long as the sidewalls are within +1-10° from the y-z plane, which may be due to processing limitations, the resulted reflector would still be functional for the photodetector to operate normally.

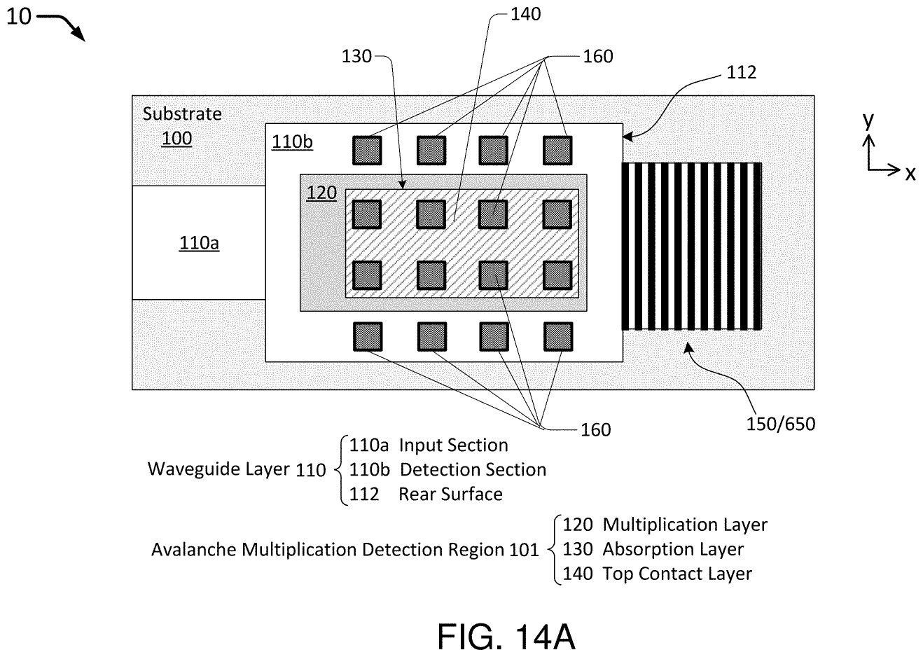

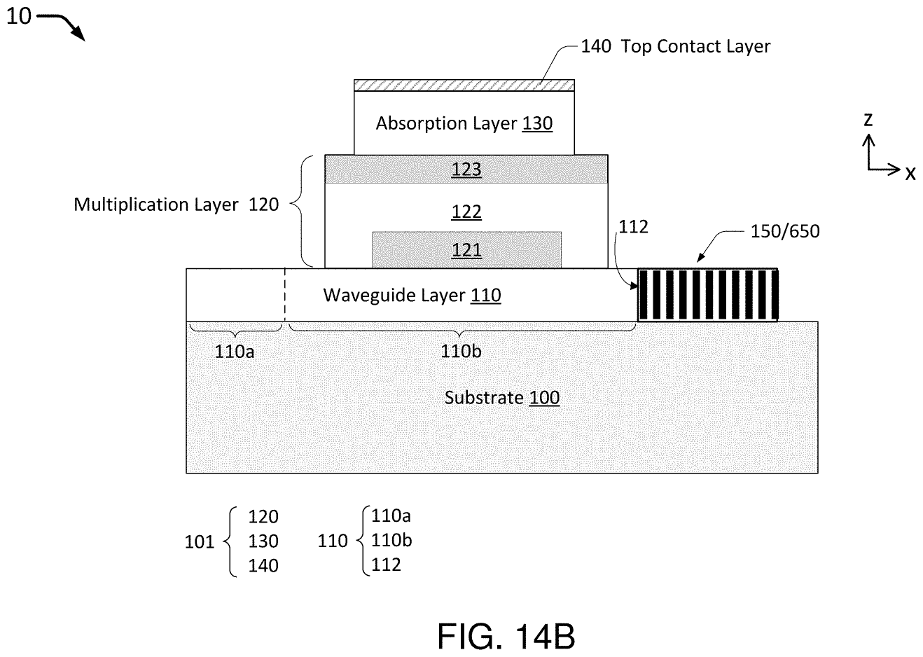

FIG. 14A and FIG. 14B illustrate an embodiment of the waveguide avalanche multiplication photodetector 10 of FIG. 1, wherein the reflector 150 thereof is realized by the one-dimensional photonic crystal reflector 650 of FIG. 6.

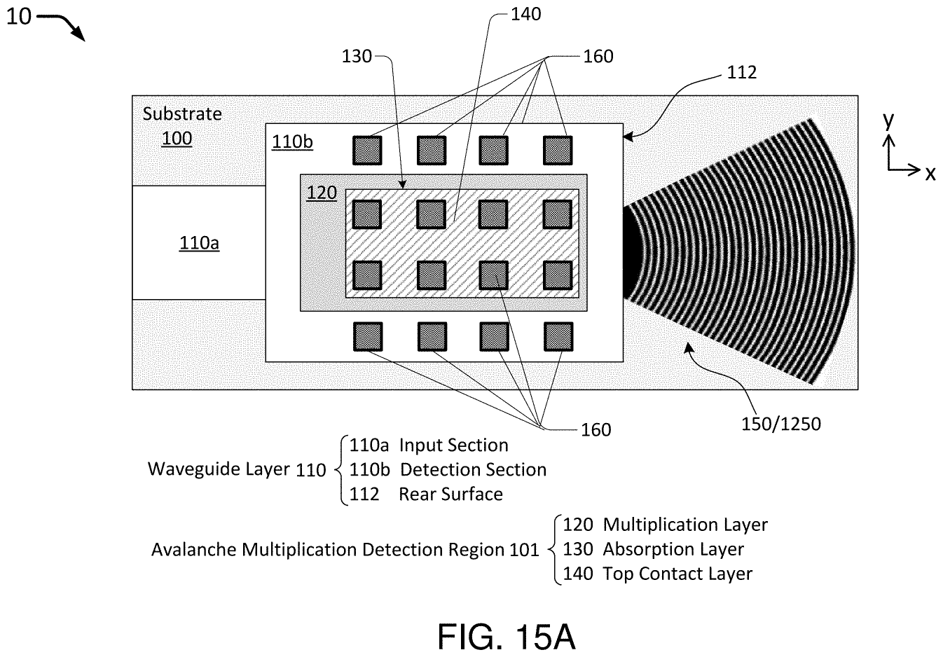

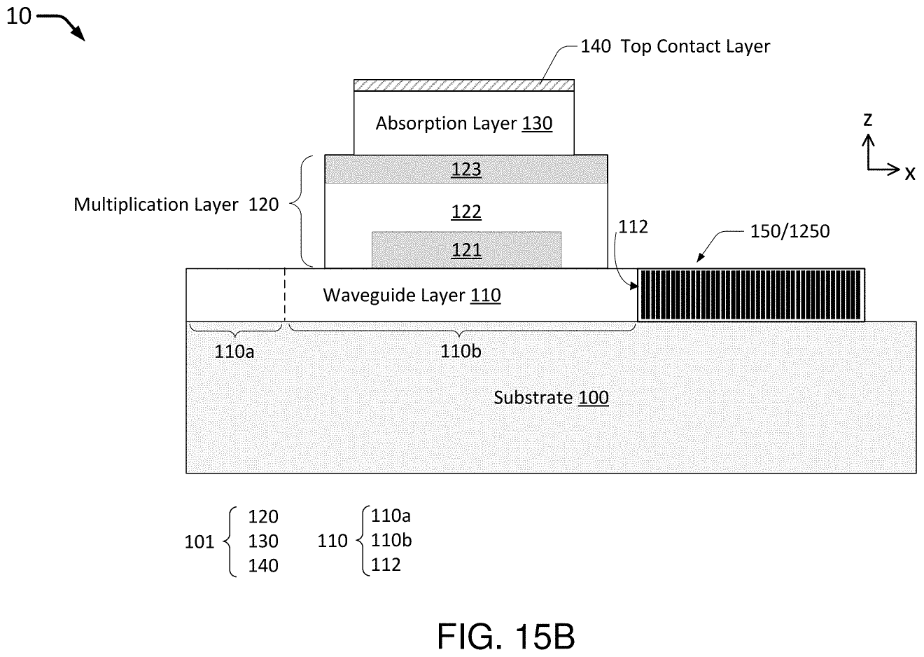

FIG. 15A and FIG. 15B illustrate an alternative embodiment of the waveguide avalanche multiplication photodetector 10 of FIG. 1, wherein the reflector 150 thereof is realized by the one-dimensional photonic crystal reflector 1250 of FIG. 12.

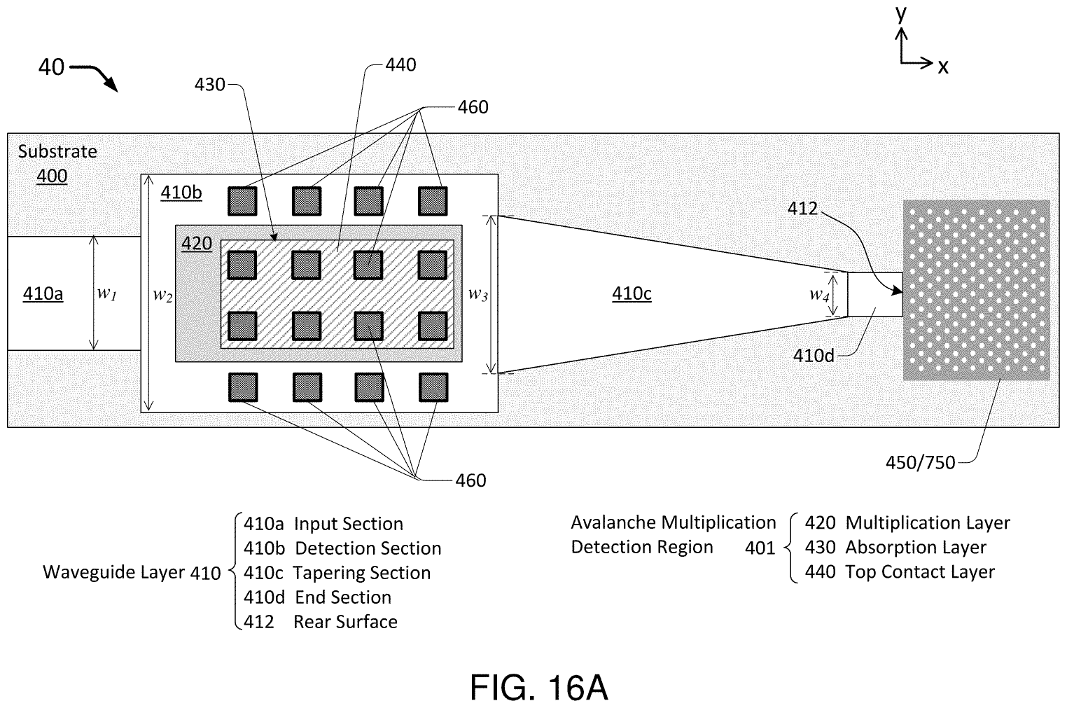

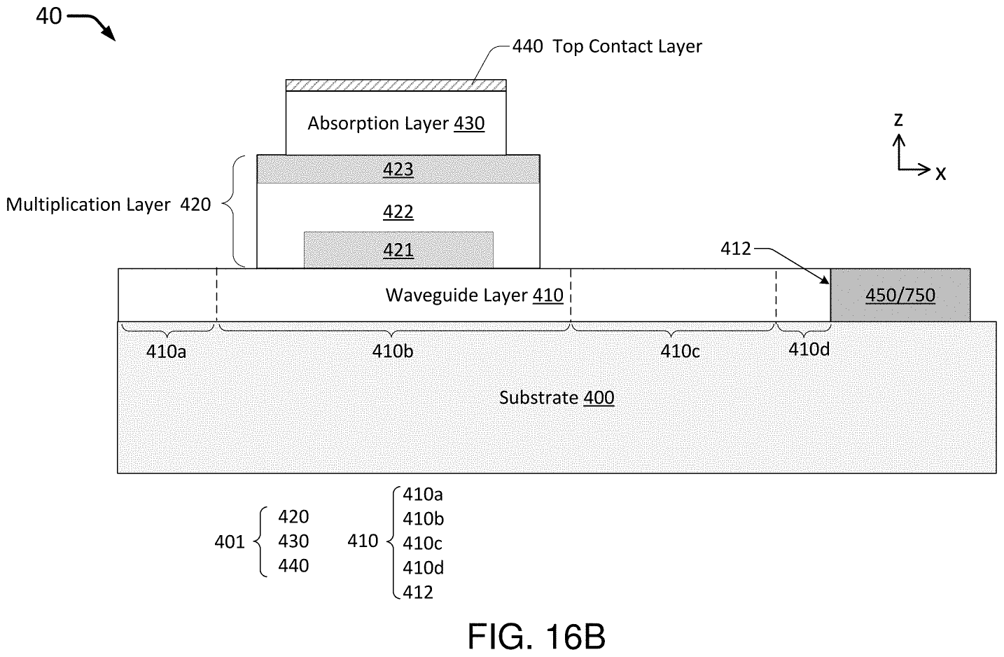

FIG. 16A and FIG. 16B illustrate an embodiment of the waveguide avalanche multiplication photodetector 40 of FIG. 4, wherein the reflector 450 thereof is realized by the two-dimensional photonic crystal reflector 750 of FIG. 7.

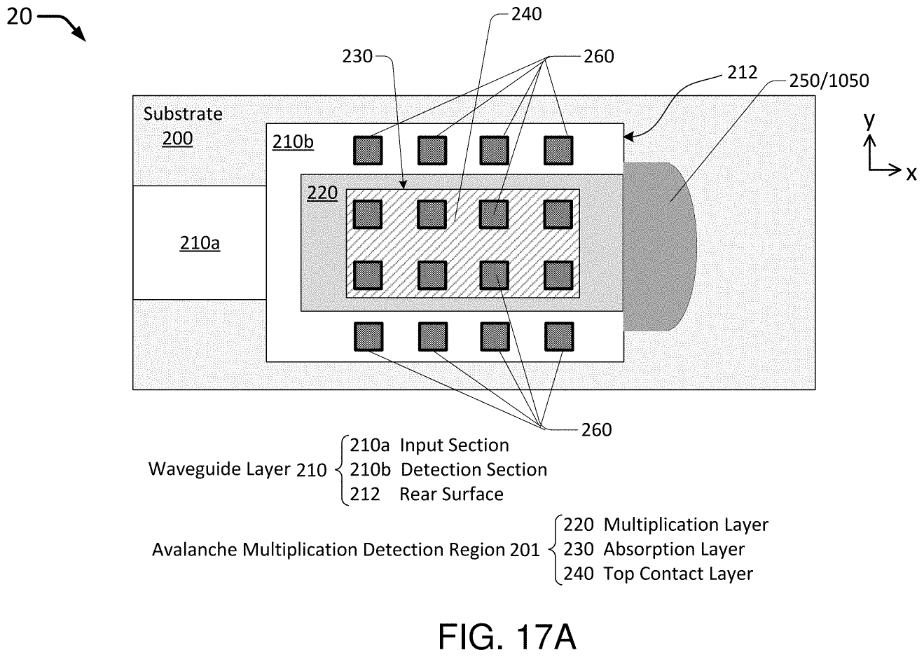

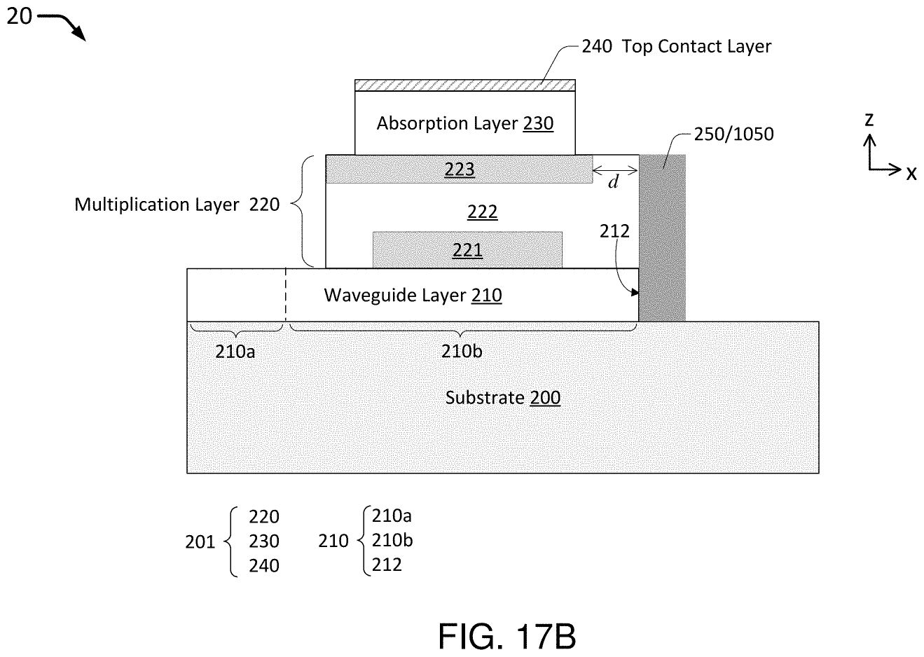

FIG. 17A and FIG. 17B illustrate an embodiment of the waveguide avalanche multiplication photodetector 20 of FIG. 2, wherein the reflector 250 thereof is realized by the bulk reflector 1050 of FIG. 10.

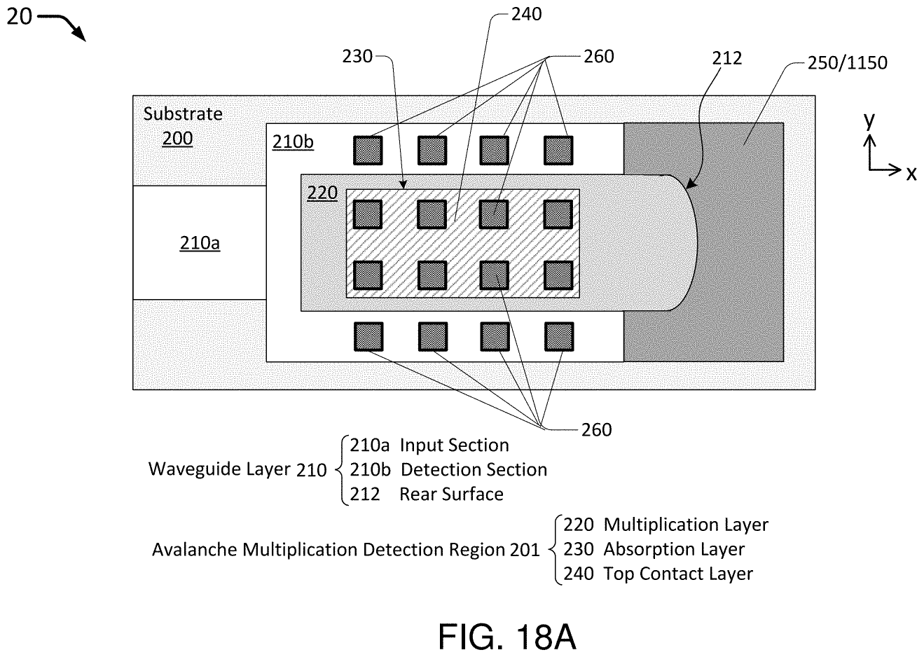

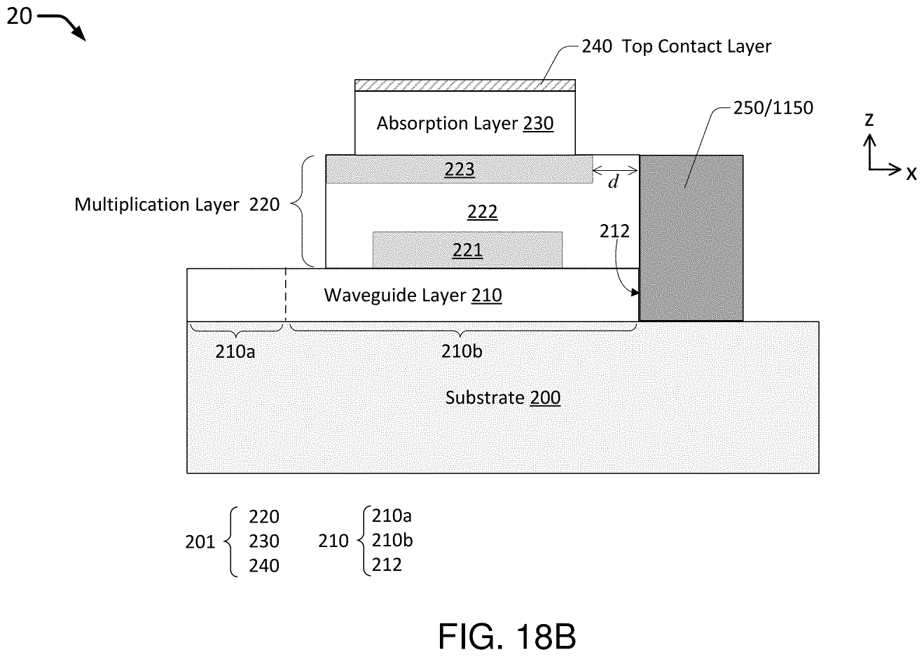

FIG. 18A and FIG. 18B illustrate an alternative embodiment of the waveguide avalanche multiplication photodetector 20 of FIG. 2, wherein the reflector 250 thereof is realized by the bulk reflector 1150 of FIG. 11.

Characteristics and benefits of the present disclosure are described with reference to various embodiments detailed above. Accordingly, the present disclosure should not be limited to these exemplary embodiments illustrating combinations of some possible unlimiting features that may exist individually or in the form of other combinations of features.

The embodiments described above are merely demonstrate certain exemplary embodiments of the present disclosure, which are used to illustrate the technical solution of the problem to be addressed, rather than to limit the present disclosure in any way. The protection scope of the present disclosure is not limited to the exemplary embodiments. Although the present disclosure has been described in detail with reference to the above-mentioned embodiments, a person skilled in the art should understand that any person familiar with the technical solution disclosed in the present disclosure is able to modify or change the technical solution recorded in the above-mentioned embodiments, and equally replace some technical features of the present invention. Nevertheless, these modifications, changes and substitutions do not separate the essence of the corresponding technical solutions from the spirit and scope of the technical solutions of the present disclosure, and are covered in the protection scope of the present application. Therefore, the protection scope of the present application shall be subject to the protection scope of the claims.

### Additional Notes

The herein-described subject matter sometimes illustrates different components contained within, or connected with, different other components. It is to be understood that such depicted architectures are merely examples, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermediate components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

Further, with respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

Moreover, it will be understood by those skilled in the art that, in general, terms used herein, and especially in the appended claims, e.g., bodies of the appended claims, are generally intended as “open” terms, e.g., the term “including” should be interpreted as “including but not limited to,” the term “having” should be interpreted as “having at least,” the term “includes” should be interpreted as “includes but is not limited to,” etc. It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to implementations containing only one such recitation, even when the same claim includes the introductory phrases “one or more” or “at least one” and indefinite articles such as “a” or “an,” e.g., “a” and/or “an” should be interpreted to mean “at least one” or “one or more;” the same holds true for the use of definite articles used to introduce claim recitations. In addition, even if a specific number of an introduced claim recitation is explicitly recited, those skilled in the art will recognize that such recitation should be interpreted to mean at least the recited number, e.g., the bare recitation of “two recitations,” without other modifiers, means at least two recitations, or two or more recitations. Furthermore, in those instances where a convention analogous to “at least one of A, B, and C, etc.” is used, in general such a construction is intended in the sense one having skill in the art would understand the convention, e.g., “a system having at least one of A, B, and C” would include but not be limited to systems that have A alone, B alone, C alone, A and B together, A and C together, B and C together, and/or A, B, and C together, etc. In those instances where a convention analogous to “at least one of A, B, or C, etc.” is used, in general such a construction is intended in the sense one having skill in the art would understand the convention, e.g., “a system having at least one of A, B, or C” would include but not be limited to systems that have A alone, B alone, C alone, A and B together, A and C together, B and C together, and/or A, B, and C together, etc. It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A photodetector, comprising:
a substrate, the substrate having a main surface substantially perpendicular to a z-direction of a Cartesian coordinate system;
a waveguide layer disposed on top of the substrate and extending along an x-direction of the Cartesian coordinate system, the waveguide layer comprising:
an input section;
a detection section concatenated with the input section along the x-direction; and
a rear surface located at an end of the detection section opposing the input section;
an avalanche multiplication detection region disposed on top of the waveguide layer, the avalanche multiplication detection region comprising:
a multiplication layer disposed on top of the waveguide layer;
an absorption layer disposed on top of the multiplication layer; and
a top contact layer disposed on top of the absorption layer; and
a reflector disposed beside the waveguide layer in the x-direction and adjacent to the rear surface, wherein the reflector comprises a one-dimensional photonic crystal, a two-dimensional photonic crystal or a bulk material.

2. The photodetector of claim 1, wherein the reflector is substantially aligned with the waveguide layer in the z-direction.

3. The photodetector of claim 1, wherein the reflector is substantially aligned with a combination of the waveguide layer and the multiplication layer in the z-direction.

4. The photodetector of claim 1, wherein the reflector has a top edge that is higher than a top edge of the multiplication layer in the z-direction, and wherein the reflector has a bottom edge that is lower than a bottom edge of the waveguide layer in the z-direction.

5. The photodetector of claim 1, wherein the one-dimensional photonic crystal is realized by a plurality of one-dimensional grooves that are periodically arranged in the waveguide layer.

6. The photodetector of claim 1, wherein the two-dimensional photonic crystal is realized by an array of holes that are periodically arranged in the waveguide layer, or by an array of holes that are periodically arranged in both the waveguide layer and the multiplication layer.

7. The photodetector of claim 1, wherein the two-dimensional photonic crystal is realized by an array of columns that are periodically arranged in the waveguide layer, or by an array of columns that are periodically arranged in both the waveguide layer and the multiplication layer.

8. The photodetector of claim 1, wherein reflector has a reflective surface that is either flat or concave.

9. The photodetector of claim 8, wherein the reflector comprises the bulk material, wherein the reflective surface is concave and located at a rear end of the bulk material, and wherein a refractive index of the bulk material is greater than or equal to a refractive index of the waveguide layer.

10. The photodetector of claim 8, wherein the reflector comprises the bulk material, wherein the reflective surface is concave and located at a front end of the bulk material, and wherein a refractive index of the bulk material is less than a refractive index of the waveguide layer.

11. A photodetector, comprising:
a substrate, the substrate having a main surface substantially perpendicular to a z-direction of a Cartesian coordinate system;
a waveguide layer disposed on top of the substrate and extending along an x-direction of the Cartesian coordinate system, the waveguide layer comprising:
an input section;
a detection section concatenated with the input section along the x-direction;
a tapering section concatenated with the detection section and opposing the input section, the tapering section extending from a first location adjacent to the detection section towards a second location along the x-direction, a y-direction dimension of the tapering section at the first location larger than a y-direction dimension of the tapering section at the second location; and
a rear surface located at an end of the tapering section opposing the input section;
an avalanche multiplication detection region disposed on top of the waveguide layer, the avalanche multiplication detection region comprising:
a multiplication layer disposed on top of the waveguide layer;
an absorption layer disposed on top of the multiplication layer; and
a top contact layer disposed on top of the absorption layer; and
a reflector disposed beside the waveguide layer in the x-direction and adjacent to the rear surface, wherein the reflector comprises a one-dimensional photonic crystal, a two-dimensional photonic crystal or a bulk material.
